(19) United States
(12) Patent Application Publication
(10) Pub. No.: US 2026/0348015 A1
(43) Pub. Date: Nov. 5, 2026

(54) GAS DISTRIBUTOR INCLUDING GAS AND COOLANT PLENUMS

(71) Applicant: Lam Research Corporation, Fremont, CA (US)

(72) Inventors: John Stephen Drewery, San Jose, CA (US); Andrea Alberti, San Francisco, CA (US); Saravanapriyan Sriraman, Fremont, CA (US); Alexander Miller Paterson, San Jose, CA (US)

(21) Appl. No.: 19/487,586

(22) PCT Filed: May 24, 2024
(86) PCT No.: PCT/US2024/031048

§ 371 Date: Nov. 25, 2025

Related U.S. Application Data
(60) Provisional application No. 63/505,987, filed on Jun. 2, 2023.

(51) Int. Cl. C23C 16/455; C23C 16/458; C23C 16/505; H01J 37/32

(52) U.S. Cl. CPC C23C 16/45572; C23C 16/45565; H01J 37/32449; C23C 16/4583; C23C 16/505

(57) ABSTRACT

Certain embodiments are directed to apparatus having first and second surfaces, gas distribution ports, a plenum interposed between the surfaces, and liquid cooling passages fluidically isolated from the plenum, and in one aspect, the liquid cooling passages have serpentine configuration(s).

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Substrate processing tools may be used to perform various processing operations, including deposition, etch, and/or other treatments on or in relation to a substrate, such as a semiconductor wafer. For example, a process chamber may be utilized to perform atomic layer deposition (ALD), atomic layer etching (ALE), chemical vapor deposition (CVD), chemical vapor etching (CVE), and/or the like, as well as plasma-enhanced and/or chemically enhanced versions of the same. In other instances, a process chamber may be used for ion implantation or cleaning purposes. Whatever the case, a substrate may be arranged on a substrate support, such as a pedestal, an electrostatic chuck (ESC), or the like, within the process chamber. As part of, for instance, a plasma-enhanced etching process, at least one gas mixture including one or more precursors may be introduced into the process chamber via a gas distributor and plasma may be struck to etch the substrate or material disposed thereon. It is noted, however, that the quality and productivity of such processes may be significantly influenced by the extent to which the temperature of such processes and/or components thereof may be controlled.

This is even more of a concern given the role temperature plays in the evolution of shrinking design rules and the adoption of increasingly complex process chemicals and semiconductor materials.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

According to some embodiments, a gas distributor is provided including both gas and coolant plenums.

Additional aspects will be set forth in the detailed description which follows, and, in part, will be apparent from the disclosure, or may be learned by practice of the disclosed embodiments and/or the claimed subject matter.

According to an embodiment, an apparatus includes a first surface, a second surface, a plurality of first gas distribution ports, a first gas distribution plenum, and one or more liquid cooling passages. The second surface opposes the first surface in a first direction. The plurality of first gas distribution ports extend in the first direction and is fluidically connected to at least one first gas inlet. The first gas distribution ports have respective distal ends forming first gas distribution openings in the first surface. The first gas distribution plenum is interposed between the first and second surfaces. The first gas distribution plenum is fluidically connected between the at least one first gas inlet and respective proximal ends of the first gas distribution ports. The one or more liquid cooling passages are interposed between the first and second surfaces. A reference plane extending in a second direction transverse to the first direction extends through central portions of the one or more liquid cooling passages. The reference plane is interposed between the first gas distribution plenum and the first surface in the first direction. Between the first and second surfaces, the one or more liquid cooling passages are fluidically isolated from the first gas distribution plenum.

In some embodiments, the apparatus may further include a cooling layer including a third surface and a fourth surface opposing the third surface in the first direction. The cooling layer may further include the one or more liquid cooling passages interposed between the third and fourth surfaces, and respective portions of the first gas distribution ports extending from the third surface through the fourth surface.

In some embodiments, the third surface may define the first surface.

In some embodiments, the cooling layer may further include a coolant inlet passage fluidically connected to at least one of the one or more liquid cooling passages, and a coolant outlet passage fluidically connected to at least one of the one or more liquid cooling passages.

In some embodiments, the cooling layer may further include a fifth surface extending between the third and fourth surfaces. The fifth surface may include a coolant inlet opening forming a proximal end of the coolant inlet passage, and a coolant outlet opening forming a distal end of the coolant outlet passage. The coolant inlet passage may include a first portion extending in a second direction transverse to the first direction. The coolant outlet passage may include a second portion extending in a third direction transverse of the first direction.

In some embodiments, the coolant inlet passage may further include a third portion fluidically connected between the first portion and the at least one of the coolant passages, the coolant outlet passage may further include a fourth portion fluidically connected between the second portion and the at least one of the coolant passages, and the third and fourth portions may extend in a fourth direction transverse to each of the second and third directions.

In some embodiments, the cooling inlet passage may be one of a plurality of cooling inlet passages fluidically connected to the one or more liquid cooling passages. The cooling outlet passage may be one of a plurality of cooling outlet passages fluidically connected to the one or more liquid cooling passages. Each of the cooling inlet passages may include a section extending radially inwards from a corresponding coolant inlet opening in the fifth surface towards a central portion of the cooling plate. Each of the cooling outlet passages may include a section extending radially inwards from a corresponding coolant outlet opening in the fifth surface towards the central portion of the cooling plate.

In some embodiments, the fourth surface of the cooling layer may include a coolant inlet opening and a coolant outlet opening. The coolant inlet opening may form a proximal end of a first portion of the coolant inlet passage. A distal end of the first portion of the coolant inlet passage may be fluidically connected to at least one of the one or more liquid cooling passages. The coolant outlet opening may form a distal end of a first portion of the coolant outlet passage. A proximal end of the first portion of the coolant outlet passage may be fluidically connected to at least one of the one or more liquid cooling passages. The first portion of the coolant inlet passage may extend in a fourth direction. The first portion of the coolant outlet passage may extend in the fourth direction.

In some embodiments, the first and fourth directions may be equivalent.

In some embodiments, the cooling inlet passage may be one of a plurality of cooling inlet passages fluidically connected to the one or more liquid cooling passages, the cooling outlet passage may be one of a plurality of cooling outlet passages fluidically connected to the one or more liquid cooling passages, each of the cooling inlet passages may include a section extending in the third direction from a corresponding coolant inlet opening in the fourth surface towards the first surface, and each of the cooling outlet passages may include a section extending in the third direction from a corresponding coolant outlet opening in the fourth surface towards the first surface.

In some embodiments, the one or more liquid cooling passages may be a plurality of liquid cooling passages, each of the plurality of cooling inlet passages may be fluidically connected to a corresponding cooling passage among the liquid cooling passages, and each of the plurality of cooling outlet passages may be fluidically connected to a corresponding cooling passage among the liquid cooling passages.

In some embodiments, the cooling layer may include a plurality of cooling layers connected to one another.

In some embodiments, the one or more liquid cooling passages may define recesses formed in at least one of the cooling layers.

In some embodiments, respective widths of the one or more liquid cooling passages in at least one direction perpendicular to the first direction may be greater than respective heights of the one or more liquid cooling passages in the first direction.

In some embodiments, the one or more liquid cooling passages may include one or more structures configured to induce turbulent flow along the one or more liquid cooling passages.

In some embodiments, the one or more liquid cooling passages may correspond to a single liquid cooling passage.

In some embodiments, the single liquid cooling passage may have a cylindrical configuration.

In some embodiments, in a view in the first direction, the one or more liquid cooling passages may include a first liquid cooling passage and a second liquid cooling passage encircling the first liquid cooling passage.

In some embodiments, in the view in the first direction, the first and second liquid cooling passages may have annular configurations.

In some embodiments, the first and second liquid cooling passages may encircle a central axis extending through the first and second surfaces in the first direction, and the one or more liquid cooling passages may further include one or more third liquid cooling passages extending radially from the central axis.

In some embodiments, the first, second, and one or more third liquid cooling passages may be fluidically connected to one another between the first and second surfaces.

In some embodiments, in a view in the first direction, the one or more liquid cooling passages may have one or more serpentine configurations.

In some embodiments, in the view in the first direction, the one or more serpentine configurations may meander about a central axis extending through the first and second surfaces in the first direction.

In some embodiments, in a view in the first direction, the one or more liquid cooling passages may form a fractal pattern.

In some embodiments, the first gas distribution ports may be positioned outside the one or more liquid cooling passages.

In some embodiments, at least one of the first gas distribution ports may be positioned outside the one or more liquid cooling passages, and at least one of the first gas distribution ports may be positioned inside the one or more liquid cooling passages.

In some embodiments, the gas distribution layer may further include the first gas distribution plenum interposed between the sixth and seventh surfaces.

In some embodiments, the sixth surface may define the second surface.

In some embodiments, the gas distribution layer further includes an eighth surface extending between the sixth and seventh surfaces, and a first gas inlet passage fluidically connected to the first gas distribution plenum. The eight surface may include the first gas inlet forming a proximal end of the first gas inlet passage. The first gas inlet passage may include a first portion extending in a fifth direction transverse to the first direction.

In some embodiments, the first gas inlet passage may further include a second portion fluidically connected between the first portion of the first gas inlet passage and the first gas distribution plenum. The second portion of the first gas inlet passage may extend in a sixth direction transverse to the fifth direction.

In some embodiments, the first and sixth directions may be equivalent.

In some embodiments, the first gas inlet passage may be one of a plurality of first gas inlet passages fluidically connected to the first gas distribution plenum, and each of the first gas inlet passages may include a section extending radially inwards from a corresponding first gas inlet in the eighth surface towards a central portion of the gas distribution layer.

In some embodiments, the gas distribution layer may further include a second portion of the coolant inlet passage and a second portion of the coolant outlet passage. The second portion of the coolant inlet passage may extend from the sixth surface through the seventh surface. The second portion of the coolant inlet passage may be fluidically connected to the first portion of the coolant inlet passage. The second portion of the coolant outlet passage may extend from the sixth surface through the seventh surface. The second portion of the coolant outlet passage may be fluidically connected to the first portion of the coolant outlet passage.

In some embodiments, the apparatus may further include a plurality of second gas distribution ports and a second gas distribution plenum. The plurality of second gas distribution ports may extend in the first direction and may be fluidically connected to a second gas inlet. The second gas distribution ports may have respective distal ends forming second gas distribution openings in the first surface. The second gas distribution plenum may be interposed between the first and second surfaces. The second gas distribution plenum may be fluidically connected between the second gas inlet and respective proximal ends of the second gas distribution ports.

In some embodiments, the first gas distribution ports may encircle the second gas distribution ports, and the first gas distribution plenum may encircle the second gas distribution plenum.

In some embodiments, the first surface may face the internal cavity in the first direction.

In some embodiments, the process chamber may define a transformer-coupled plasma etch chamber.

In some embodiments, the second surface may be exposed to an ambient environment.

In some embodiments, the pedestal may face the first surface in the first direction.

In some embodiments, the liquid coolant may be non-conductive.

In some embodiments, the liquid coolant may be non-polar.

In some embodiments, the liquid coolant may include at least one of a polyfluorinated compound, a perfluorinated compound, a segregated hydrofluoroether compound, a metal oxide, and a carbon nanotube.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals refer to similar elements.

FIG. 1 schematically illustrates a substrate processing system, which may not only be used to process a semiconductor wafer, but may also be capable of thermally controlling the temperature of a gas distributor according to some embodiments.

FIG. 2 schematically illustrates a perspective view of the gas distributor of FIG. 1 according to some embodiments.

FIGS. 4 and 3 schematically illustrates cross-sectional view of the gas distributor of FIG. 2 in a partially assembled state according to some embodiments.

FIGS. 5 and 6 schematically illustrate perspective and orthographic views of a first portion of the gas distributor of FIG. 2 according to some embodiments.

FIGS. 7 and 8 schematically illustrate cross-sectional views of the first portion of the gas distributor of FIGS. 5 and 6 taken respectively along sectional lines 7-7 and 8-8 according to some embodiments.

FIGS. 9 and 10 schematically illustrate cross-sectional views of a first portion of a gas distributor according to some embodiments.

FIG. 11 schematically illustrates a cross-sectional view of the first portion of the gas distributor of FIGS. 5 and 6 taken along sectional line 11-11 according to some embodiments.

FIGS. 12, 13, 14, 15, and 16 schematically illustrate sectional views of other first portions of a gas distributor according to some embodiments.

FIGS. 17 and 18 schematically illustrate perspective views of a second portion of the gas distributor of FIG. 2 according to some embodiments.

FIG. 19 schematically illustrates an orthographic view of the second portion of the gas distributor of FIG. 2 according to some embodiments.

FIG. 20 schematically illustrates a cross-sectional view of the second portion of the gas distributor of FIG. 2 according to some embodiments.

FIG. 21 schematically illustrates an enlarged detail view of portion 21 depicted in FIG. 20 according to some embodiments.

FIG. 22 schematically illustrates an enlarged detail view of portion 22 depicted in FIG. 21 according to some embodiments.

FIG. 23 schematically illustrates an enlarged detail view of portion 23 depicted in FIG. 19 according to some embodiments.

FIG. 24 schematically illustrates a cross-sectional view of the second portion of the gas distributor of FIG. 2 taken along sectional line 24-24 according to some embodiments.

FIG. 25 schematically illustrates a cross-sectional view of the second portion of the gas distributor of FIG. 2 according to some embodiments.

FIGS. 26 and 27 schematically illustrate cross-sectional views of a second portion of a gas distributor according to some embodiments.

FIG. 28 schematically illustrates an orthographic view of a ring assembly of the gas distributor of FIG. 2 according to some embodiments.

FIG. 29 schematically illustrates a perspective view of a ring structure of the ring assembly of FIG. 28 according to some embodiments.

FIG. 30 schematically illustrates a cross-sectional view of a portion of the gas distributor of FIG. 2 according to some embodiments.

FIGS. 31 and 32 schematically illustrate various perspective views of a connection block of the gas ring assembly of FIG. 28 according to some embodiments.

FIG. 33 schematically illustrates a perspective view of a gas distributor in a partially assembled state according to some embodiments.

FIG. 34 schematically illustrates a cross-sectional view of the partially assembled gas distributor of FIG. 33 according to some embodiments.

FIG. 35 schematically illustrates a perspective view of a gas distributor in a partially assembled state according to some embodiments.

FIG. 36 schematically illustrates a cross-sectional view of the partially assembled gas distributor of FIG. 35 according to some embodiments.

FIG. 37 schematically illustrates a multi-station processing tool according to some embodiments.

### DETAILED DESCRIPTION OF SOME EMBODIMENTS

In the following description, numerous specific details are set forth in order to provide a thorough understanding of various embodiments. The disclosed embodiments may be practiced without some or all of these specific details. In other instances, well-known process operations have not been described in detail to not unnecessarily obscure the disclosed embodiments. While the disclosed embodiments will be described in conjunction with specific embodiments, it will be understood that it is not intended to limit the disclosed embodiments.

In this application, the terms “semiconductor wafer,” “wafer,” “substrate,” “wafer substrate” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of the disclosed embodiments include various articles, such as printed circuit boards, magnetic recording media, magnetic recording sensors, mirrors, optical elements, micro-mechanical devices, and the like.

### Context

As feature sizes continue to shrink, high aspect ratio (HAR) structures are becoming more common. HAR structures typically exhibit features having height-to-width ratios greater than 5:1, 20:1, or even upwards of 50:1. Fabrication of such features using conventional wet etch techniques poses a number of challenges including degraded efficiency due, at least in part, to reduced diffusion and surface charge layer overlap in geometrically confined spaces. Dry etch techniques utilizing gas and/or vapor-phase etch chemistries seek to at least address these issues, but as previous indicated, the quality and productivity of such processes may be significantly influenced by how well the temperature of the processes and components thereof may be controlled. Typically, the reactive species of the gas and/or vapor-phase precursors are produced by exciting molecules within a plasma discharge through a dielectric window on a process chamber, but cooling the dielectric window can be difficult. This is especially true with respect to conventional air-cooling techniques that utilize relatively large, noisy, expensive, and inefficient fans and/or compressors to extract heat from at least the dielectric window. To this end, air-cooling devices are usually captive to ambient temperature conditions, as well as victims to the effects of magnetostriction, which can cause the air-cooling devices themselves to introduce heat to the system and audibly hum. Accordingly, one or more embodiments stem from the recognition that liquid-cooling techniques offer increased capacity to transfer thermal energy relative to air-cooling solutions, and thereby, offer greater thermal performance in potentially smaller working envelopes. In turn, this may allow for higher plasma density to be obtained within a process chamber as more heat may be extracted from the dielectric window. Furthermore, liquid-cooling techniques provide greater control over the cooling system at least because such techniques provide increased control over inlet temperatures and flow rates, not to mention enabling environmentally sealed solutions.

### Systems for Semiconductor Processing

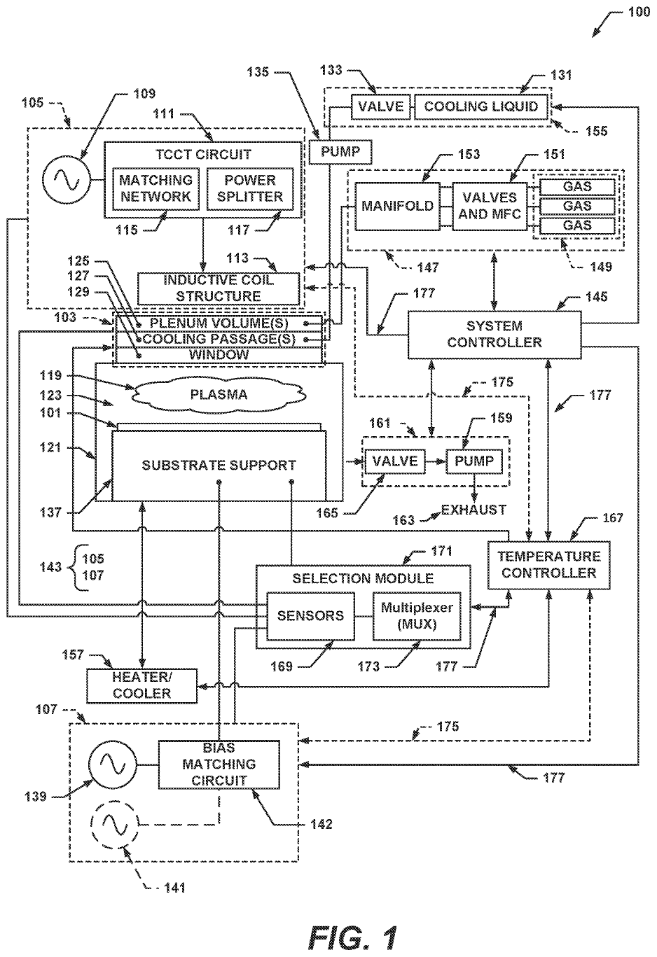

FIG. 1 schematically illustrates a substrate processing system, which may not only be used to process a semiconductor wafer, but may also be capable of thermally controlling the temperature of a gas distributor according to some embodiments.

Referring to FIG. 1, substrate processing system (or system) 100 is shown and may be used for etching substrate 101 or material disposed thereon. In some embodiments, system 100 may be utilized to regulate or control the temperature of gas distributor 103 before, during, and/or after one or more etching processes, which may be driven using thermal and/or plasma energy. Although particular reference will be made to an inductively coupled plasma (ICP) etching system, any other type of ICP or transformer coupled plasma (TCP) etching system and/or other plasma processing system may be used. In some implementations, system 100 may include radio frequency (RF) generating systems 105 and 107. RF generating system 105 may include RF source 109 (e.g., a transformer coupled plasma RF generator) connected to transformer coupled capacitive tuning (TCCT) circuit 111, which may be configured to output current to inductive coil structure 113.

In some embodiments, TCCT circuit 111 may include matching network 115 and power splitter 117. Matching network 115 may be connected by a transmission line to RF source 109 and may be configured to match impedance of RF source 109 to at least one remaining portion of TCCT circuit 111, such as power splitter 117 and/or inductive coil structure 113. Although TCCT circuit 111 may have or include any number of suitable electrical designs, at least one configuration is shown and described in commonly assigned U.S. Patent Application Publication No. 2013/0135058, applied for by Long et al., which is hereby incorporated by reference for all purposes as if fully set forth herein.

Inductive coil structure 113 may include a single inductive coil, a pair of inductive coils, an inner inductive coil pair and an outer inductive coil pair, or any other configuration. In this manner, power splitter 117 may be used to control a relative amount of inductive current supplied to the coils of inductive coil structure 113, and thereby, to generate one or more time-varying magnetic fields, which may be used to spark, induce, or excite plasma 119 within process chamber 121. Depending on the process(es) being performed via process chamber 121, inductive coil structure 113 may be driven in a capacitive mode to produce plasma 119 having a relatively low density and/or an inductive mode to produce plasma 119 having a relatively high density. Further, the coils of inductive coil structure 113 may have any suitable configuration, such as planar coils, cylindrical coils, half-toroidal coils, etc. In some embodiments, inductive coil structure 113 may be arranged outside of process chamber 121 and adjacent to gas distributor 103 to, for example, reduce the potential for contamination from the material (e.g., metallics) of inductive coil structure 113.

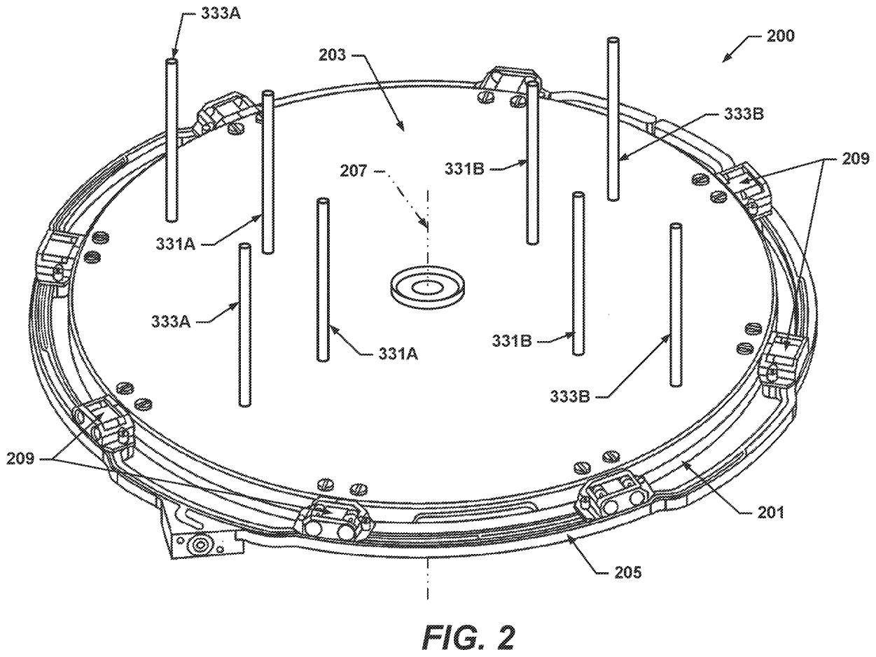

Process chamber 121 may have any suitable geometric configuration defining one or more internal cavity regions, such as internal cavity region 123, within which at least substrate 101 may be processed. In some cases, process chamber 121 may include gas distributor 103 arranged along at least one of its sides or surfaces. Although gas distributor 103 is shown having a “top plate” configuration, embodiments are not limited thereto. For instance, gas distributor 103 may have a showerhead or other type of configuration. As will be discussed later in more detail, gas distributor 103 may include one or more plenum volumes 125, one or more liquid cooling passages 127, and window 129. For descriptive convenience, plenum volume(s) 125 and liquid cooling passage(s) 127 will be collectively and/or individually referenced as plenum volume 125 and liquid cooling passage 127, unless the context dictates otherwise. In general, however, plenum volume 125 may be arranged between inductive coil structure 113 and window 129, which may be a dielectric window extending along at least one wall (or side) of process chamber 121. Liquid cooling passage 127 may be arranged between plenum volume 125 and window 129, which may interface with internal cavity region 123 of process chamber 121. Example gas distributors and components thereof will be described in more detail in association with FIGS. 2-36.

According to various embodiments, the temperature of gas distributor 103 may be regulated by controlling the flow of one or more conductive cooling fluids, e.g., liquid coolant 131, through liquid cooling passage 127 via at least one regulator, such as valve 133, and, for example, pump 135. In some cases, controlling the temperature of gas distributor 103 may also facilitate the control of the temperature of one or more walls of process chamber 121 and/or one or more gases flowing through gas distributor 103. It is also noted that controlling the temperature of gas distributor 103, the walls of process chamber 121, and/or the gas(es) flowing through gas distributor 103 may prevent or at least reduce the likelihood of condensation being formed therein or thereon.

Process chamber 121 may also include substrate support 137 configured to support substrate 101 at least during one or more semiconductor processes. Substrate support 137 may be or include an electrostatic chuck, a mechanical chuck, and/or any other suitable type of chuck/support structure. During at least one semiconductor process, plasma 119 may be generated inside process chamber 121. Plasma 119 may be used to, for example, etch substrate 101 and/or material disposed thereon.

RF generating system 107 may include one or more bias RF sources 139 and 141 and bias matching circuit 142. RF source 139 may provide a bias RF voltage to bias substrate support 137 during operation. Bias matching circuit 142 may match impedance of RF sources 139 and 141 to an electrode assembly of, for example, substrate support 137. Collectively, RF generating systems 105 and 107 may form, and thereby, may be referred to as RF generating system 143, which may be controlled by system controller 145.

Gas delivery system 147 may be used to supply one or more gases, such as a gas mixture, to process chamber 121 before, during, and/or after at least one semiconductor process. In some cases, gas delivery system 147 may be disposed adjacent to gas distributor 103. Gas delivery system 147 may include one or more process gas sources 149, at least one metering system 151, and manifold 153. The at least one metering system 151 may include one or more valves and one or more mass flow controllers that, together with manifold 153, may be configured to mix and/or supply one or more process gases to process chamber 121 via at least gas distributor 103.

Conductive cooling fluid delivery system 155 may be used to flow, for instance, liquid coolant 131 through liquid cooling passage 127 via at least one regulator, such as valve 133, and, for example, pump 135. Liquid coolant 131 may, in some implementations, include at least one of an aliphatic compound, a polyfluorinated compound, a perfluorinated compound, a segregated hydrofluoroether compound, a glycol, a metal, a liquid metal, a metal oxide, a carbon nanotube, diamond, and an ionic liquid. In some cases, liquid coolant 131 may be non-conductive and non-polar. For instance, liquid coolant 131 may be one of 3M™'s Fluorinert™ compounds, one of 3M™M's Novec™ compounds, one of Solvay™M's Galden™ compounds, and/or the like. As previously mentioned, liquid coolant 131 may be utilized to cool, for instance, gas distributor 103, but embodiments are not limited thereto. Heater and/or cooler (hereinafter, temperature regulator) 157 may be used to heat and/or cool substrate support 137 to a determined temperature or temperature range. In some cases, temperature regulator 157 may include one or more resistive heating elements and/or one or more coolant passages arranged in association with at least one of process chamber 121, gas distributor 103, and/or substrate support 137.

According to various embodiments, gases may exit process chamber 121 by way of an exhaust gas port or outlet fluidically coupled to, for instance, vacuum pump 159, which may be part of exhaust system 161. Vacuum pump 159 may be a one-or two-stage mechanical dry pump and/or a turbomolecular pump. In this manner, gas(es) may be drawn out of process chamber 121 to exhaust 163 to maintain a suitably low pressure within process chamber 121. To this end, a closed-loop flow restriction device 165, such as a throttle valve or a pendulum valve, may be controlled by way of system controller 145 to further ensure a suitably low pressure in process chamber 121. In some cases, exhaust 163 may be a scrubbed exhaust.

System controller 145 may be used to control at least one semiconductor process performed on or relative to substrate 101, such as an etching process. In this manner, system controller 145 may be configured to operate system 100 by executing one or more sequences of one or more instructions defining at least one process recipe. For example, system controller 145 may not only be configured to monitor various process parameters, such as, for example, temperature, pressure, power, grounding, timing, distancing, etc., but may also be configured to control, for instance, delivery of one or more gas mixtures, striking, maintaining, and extinguishing plasma 119, removal of reactants, supply of liquid coolant 131 to liquid cooling passage 127, mechanical movement of at least one of gas distributor 103, substrate support 137, and substrate 101, and/or the like. System 100 may also include temperature controller 167 configured to control the temperature of at least one of gas distributor 103, process chamber 121, and substrate support 137. In this manner, system controller 145 and/or temperature controller 167 may include, for instance, application-specific integrated circuits (ASIC), programmable logic devices (e.g., field-programmable gate arrays (FPGAs)), and/or the like, to control and/or exchange information with various components of system 100.

According to some implementations, system controller 145 may receive input signals from sensors 169, and based on the input signals, control operation of RF sources 109, 139, and 141, bias matching circuit 142, temperature regulator 157, and/or one or more of the other components of system 100. Sensors 169 may be located in and/or on RF generating systems 143, process chamber 121, gas distributor 103, substrate support 137, and/or elsewhere in system 100. Various sensors among sensors 169 may detect, for example, supplied RF voltages, temperatures, gas and/or coolant flow rates, and gas and/or coolant pressures, etc.

Selection module 171 may be connected to temperature controller 167 and may include sensors(s) 169 (e.g., multi-range voltage sensor(s)) and multiplexer (MUX) 173. In some cases, selection module 171 may be included in process chamber 121 or may be external to process chamber 121, as shown. Multiplexer 173 may be configured to select one or more signals received from one or more of sensors 169 to send to, for instance, temperature controller 167. Temperature controller 167 may control the temperature of gas distributor 103, substrate support 137, and/or other components of system 100 based on the voltage signals received from multiplexer 173. In some cases, temperature controller 167 may receive RF voltage signals, indicating RF voltages generated by RF generating systems 143 from system controller 145 and/or directly from RF generating systems 143, as shown by phantom lines 175. The RF voltage signals may additionally or alternatively be utilized to control the temperature of, for example, gas distributor 103, substrate support 137, and/or other components of system 100.

Ethernet for control automation technology (EtherCAT) mediums (or cables) 177 may exist between EtherCAT interfaces of RF generating systems 143, system controller 145, temperature controller 167, and selection module 171. Analog mediums (or cables), for example signal lines 175, may exist between RF generating systems 143 and temperature controller 167. Relatively fast parameter transmission via the EtherCAT interfaces and/or the analog interfaces may be provided for relatively quick/real-time response (e.g., 1 millisecond (ms) response time or less), but embodiments are not limited thereto. In some cases, the EtherCAT interfaces may each have a 1 kilohertz (kHz) data transfer rate, but implementations are not limited thereto.

### Example Gas Distributors

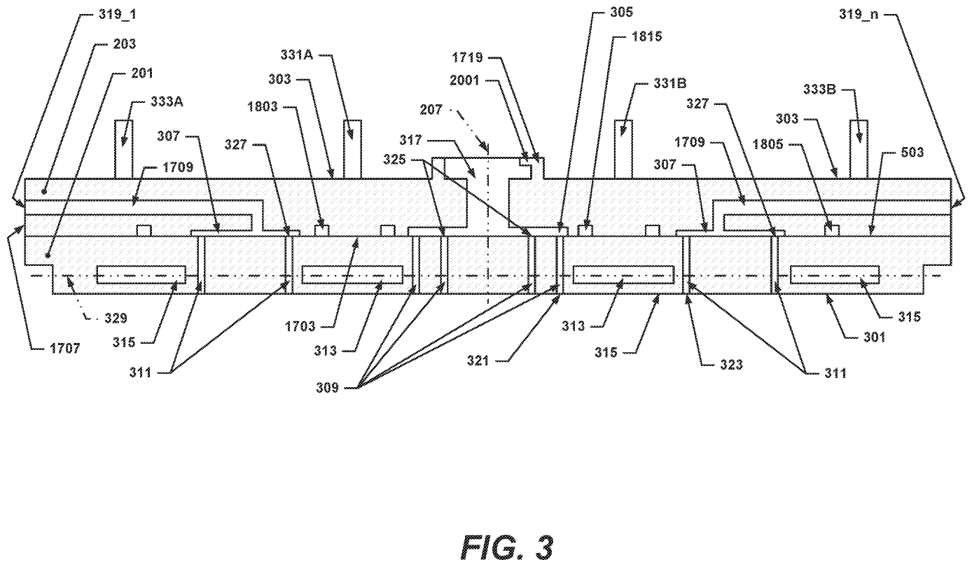

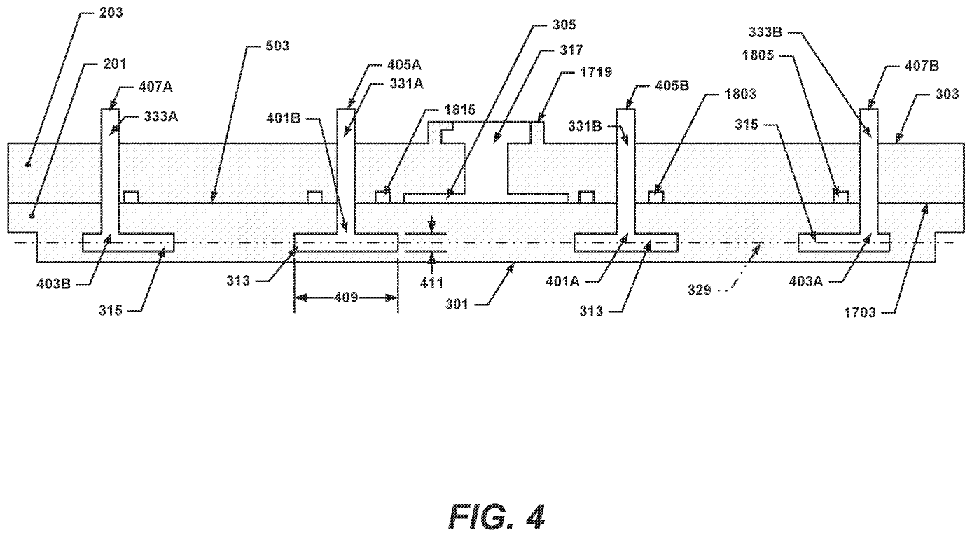

FIG. 2 schematically illustrates a perspective view of the gas distributor of FIG. 1 according to some embodiments. FIGS. 4 and 3 schematically illustrate various cross-sectional views of the gas distributor of FIG. 2 in a partially assembled state according to some embodiments.

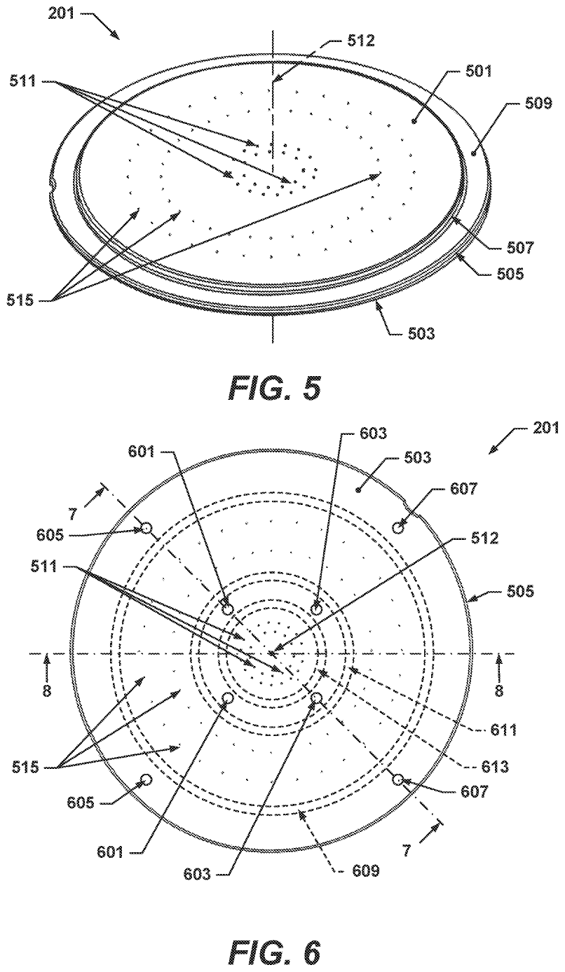

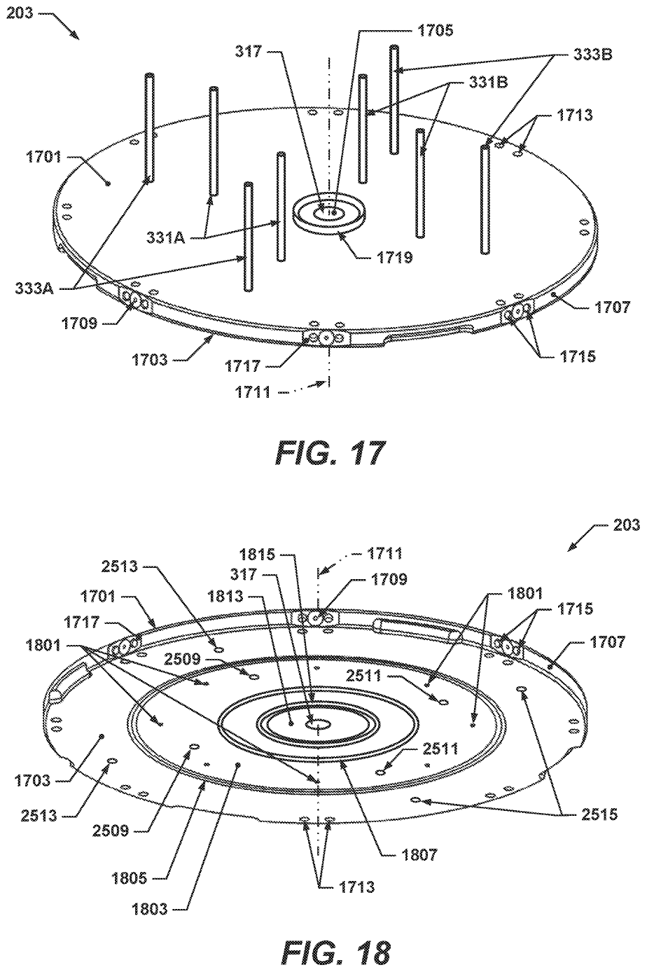

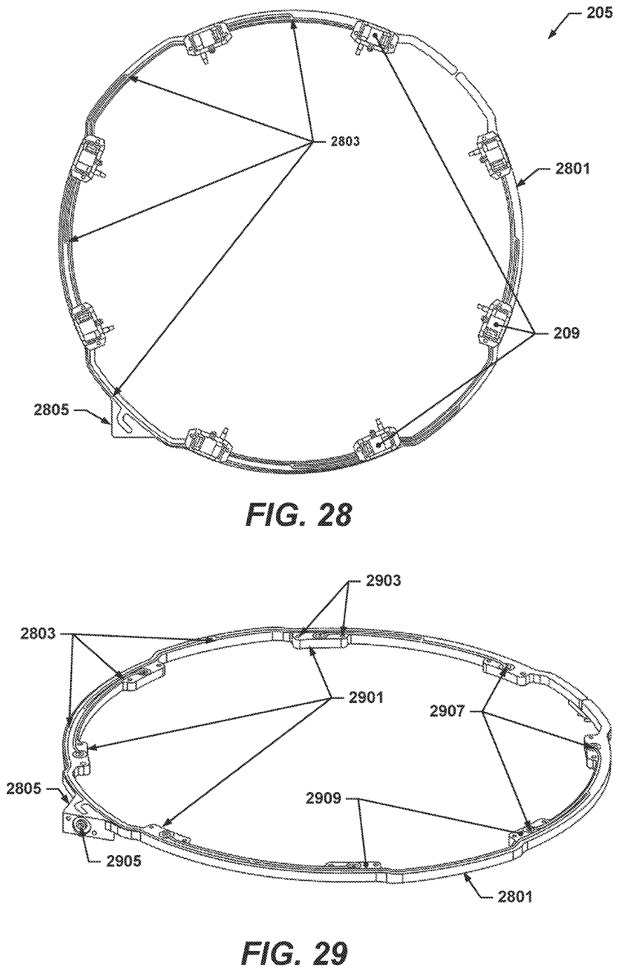

Referring to FIGS. 2, 4, and 3, gas distributor 200 may, in some embodiments, have a multi-piece (e.g., three-piece) configuration including first portion 201, second portion 203, and third portion 205. In some cases, first and second portions 201 and 203 may have generally circular, plate-like configurations and may be made of one or more electrically insulating materials, such as alumina, silicon nitride, aluminum nitride, a doped silicon carbide, quartz, and/or the like. Third portion 205 may be an assembly of components and may have a generally ring-like (or annular) configuration that at least partially encircles first portion 201 and second portion 203 in an assembled state of gas distributor 200. In some cases, first and second portions 201 and 203 may be layers of a monolithic body, or may be plates joined together using, for instance, one or more fasteners, e.g., anchors, bolts, clips, nuts, rivets, screws, ties, and/or the like, and/or any other suitable bonding technique, e.g., adhesive bonding, diffusion bonding, soldering, welding, etc. It is also contemplated that at least one of first and second portions 201 and 203 may be formed of one or more layers. Whatever the case, gas distributor 200 may have first surface 301 and second surface 303 opposing first surface 301 in a first direction, such as an axial direction of gas distributor 200. The axial direction may extend parallel (or substantially parallel) to axis 207, which may be a center axis of gas distributor 200. To this end, first surface 301 may face substrate 101 in the first direction as part of at least one stage of a processing operation utilizing process chamber 121. First portion 201 will be described in more detail in association with at least FIGS. 5-16, and second portion 203 will be more fully delineated in conjunction with at least FIGS. 17-27. Third portion 205 will be described later with reference to at least FIGS. 28-32.

Before describing the various portions of gas distributor 200 in more detail, it is generally noted that gas distributor 200 may include one or more gas distribution plenums (e.g., first and second gas distribution plenums 305 and 307), one or more pluralities of gas distribution ports (e.g., first and second gas distribution ports 309 and 311), and one or more liquid cooling passages (e.g., first and second liquid cooling passages 313 and 315). In some embodiments, the one or more pluralities of gas distribution ports may extend in the first direction between second surface 303 and first surface 301, and may be fluidically connected to corresponding gas inlets. For instance, first gas distribution ports 309 may be fluidically connected to first gas inlet 317 by way of first gas distribution plenum 305 and second gas distribution ports 311 may be fluidically connected to one or more second gas inlets (e.g., second gas inlets 319_1, . . . , 319_n, where n is a positive integer greater than or equal to one) by way of second gas distribution plenum 307. The one or more pluralities of gas distribution ports may have respective distal ends forming corresponding pluralities of gas distribution openings (e.g., first and second gas distribution openings 321 and 323) in first surface 301. To this end, first and second gas distribution plenums 305 and 307 may be interposed between second surface 303 and first surface 301 in the first direction, and may be fluidically connected to respective proximal ends (e.g., first and second proximal ends 325 and 327) of the one or more pluralities of gas distribution ports.

According to various embodiments, first reference plane 329 may extend through central portions of the one or more liquid cooling passages and may be arranged between the one or more gas distribution plenums and first surface 301 in the first direction. It is noted that the one or more liquid cooling passages may be fluidically isolated from the one or more gas distribution plenums and the one or more gas distribution ports within gas distributor 200.

That being said, some of the gas distribution ports may, in various implementations, extend through the one or more liquid cooling passages, as will become more apparent below. The one or more liquid cooling passages, such as first and second liquid cooling passages 313 and 315 may correspond to liquid cooling passage 127 described in association with system 100. In this manner, the one or more liquid cooling passages may be configured to flow liquid coolant (e.g., liquid coolant 131) therethrough to control or otherwise regulate the temperature of gas distributor 200. As such, the one or more liquid cooling passages may be fluidically connected to corresponding coolant inlet/outlet passages (e.g., first and second coolant inlet/outlet passages 331A/B and 333A/B) at respective distal ends, and thereby, forming corresponding coolant outlet/inlet openings (e.g., first and second coolant outlet/inlet openings 401B/A and 403B/A) of the coolant inlet/outlet passages. The coolant inlet/outlet passages may also have respective proximal ends forming corresponding coolant inlet/outlet openings (e.g., first and second coolant inlet/outlet openings 405A/B and 407A/B).

In various implementations, respective widths 409 of the liquid cooling passage(s) may be larger (e.g., substantially larger) than corresponding heights 411 of the liquid cooling passages. For instance, widths 409 may be about an order of magnitude greater than heights 411, but embodiments are not limited thereto. For instance, widths 409 may be about two, three, four, or the like, times greater than the heights 411. Further, the liquid cooling passage(s) may be configured to support a relatively high flow velocity of liquid coolant 131 therethrough to promote cooling of gas distributor 200. For instance, the one or more liquid cooling passages may be configured to flow up to about 10 liters per minute (L/min), such as about 3 L/min to about 8 L/min, for instance, 5 L/min to about 9 L/min, e.g., about 3 L/min to about 7 L/min. It is noted, however, that the flow rate of liquid coolant 131 through the liquid cooling passage(s) may be set based on the processing operation being performed using gas distributor 200. It is also contemplated that the liquid cooling passage(s) may include one or more internal features or impingements (e.g., the presence of one or more gas distribution ports) to promote turbulent flow therein that, in turn, may also promote cooling of gas distributor 200. For example, the Reynolds number of the flow may be at least greater than 4000, but embodiments are not limited thereto. Accordingly, the liquid cooling passages may be configured to remove up to about 10 kilowatts (kW) of heat from gas distributor 200. In some cases, the liquid cooling passages may be configured to remove a range of heat flux from about 100 W to about 10 kW, such as about 1 kW to about 5 kW, e.g., about 2 kW to about 5 kW, for instance, about 3 kW to about 4 kW, but embodiments are not limited thereto.

Further, the configuration of the liquid cooling passage(s) may allow for a more uniform temperature profile across gas distributor 200.

### Example First Portions

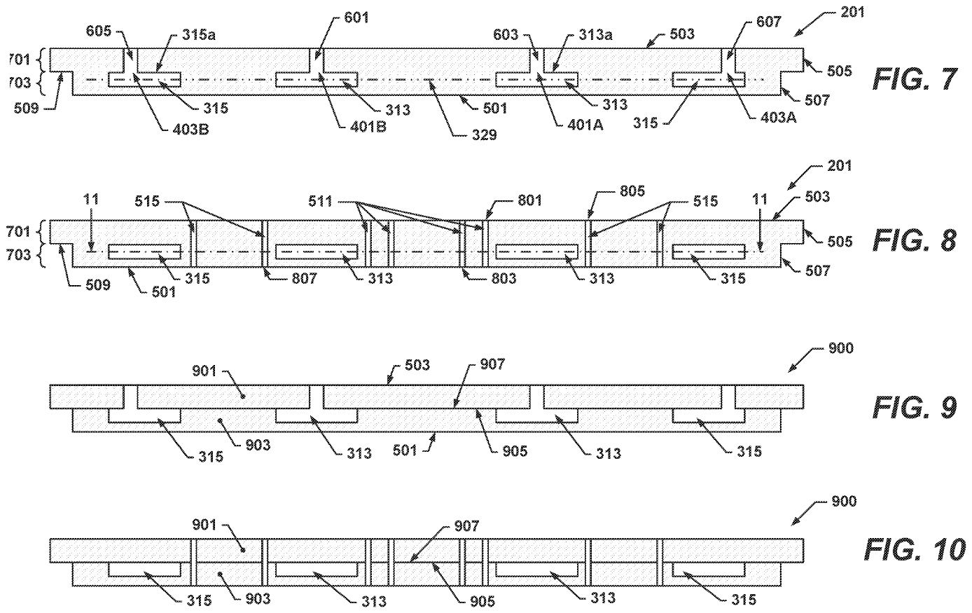

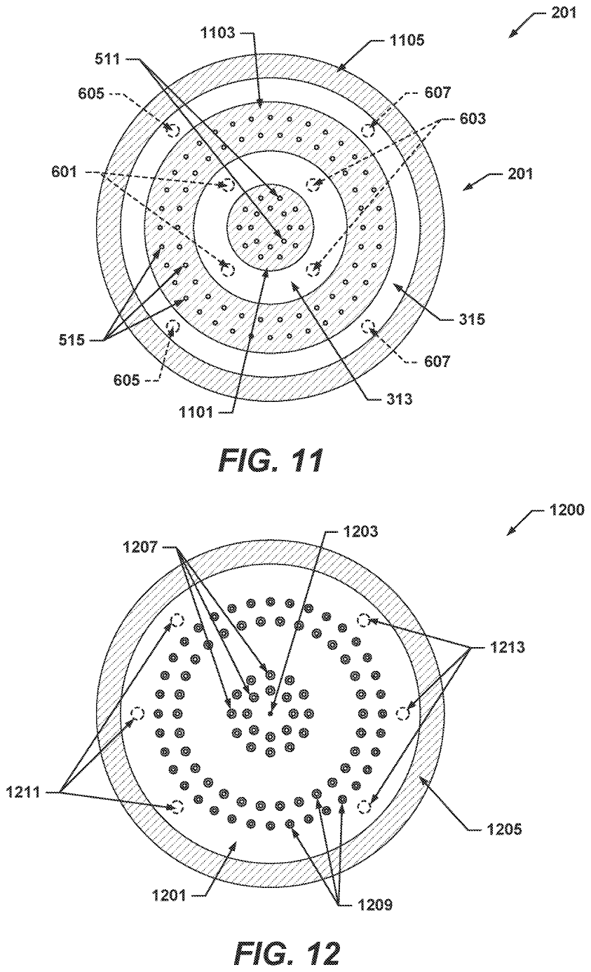

FIGS. 5 and 6 schematically illustrate perspective and orthographic views of a first portion of the gas distributor of FIG. 2 according to some embodiments. FIGS. 7 and 8 schematically illustrate cross-sectional views of the first portion of the gas distributor of FIGS. 5 and 6 according to some embodiments. FIG. 11 schematically illustrates a cross-sectional view of the first portion of the gas distributor of FIGS. 5 and 6 taken along sectional line 11-11 according to some embodiments.

With reference to FIGS. 5-8 and 11, first portion 201 may include first (e.g., lower) surface 501, second (e.g., upper) surface 503, third (e.g., first outer) surface 505, fourth (e.g., second outer) surface 507, and fifth (e.g., intermediate) surface 509. In this manner, first portion 201 may have a stepped configuration with second surface 503, third surface 505, and fifth surface 509 at least partially bounding or defining upper section 701, and first surface 501 and fourth surface 507 at least partially bounding or defining lower section 703. Fifth surface 509 may, in some cases, be an annular vacuum sealing surface configured to be vacuum sealed to, for instance, a temperature-controlled wall (or surface) of process chamber 121. It is generally noted that first surface 501 may correspond to first surface 301 described in association with at least FIGS. 3 and 4.

First gas distribution ports 511 may extend between second surface 503 and first surface 501 in an axial direction along axis 512 in a first area of first portion 201. Axis 513 may, in some implementations, define a central axis of first portion 201. Second gas distribution ports 515 may extend between second surface 503 and first surface 501 in the axial direction along axis 512 in a second area of first portion 201. In some cases, the first and second areas may be first and second annular areas of first portion 201 with the second annular area encircling the first annular area, but embodiments are not limited thereto. To this end, first gas distribution ports 511 may respectively include first gas inlets 801 and first gas outlets 803, and second gas distribution ports 515 may respectively include second gas inlets 805 and second gas outlets 807. First and second gas distribution ports 511 and 515 may correspond to first and second gas distribution ports 309 and 311 described in association with at least FIGS. 3 and 4. As will become more apparent below, first gas distribution ports 511 may be fluidically isolated from second gas distribution ports 515 within gas distributor 200, but embodiments are not limited thereto. For instance, first and second gas distribution ports 511 and 515 may be fluidically connected to one another by way of a common supply plenum in gas distributor 200. Whatever the case, first and second gas outlets 803 and 807 may output one or more gases in process chamber 121 before, during, and/or after at least one stage of a processing operation.

According to some embodiments, one or more liquid cooling passages (e.g., first and second liquid cooling passages 313 and 315) may be formed in an area interposed between second and first surfaces 503 and 501 of first portion 201. For descriptive convenience, the one or more liquid cooling passages formed in first portion 201 will, hereinafter, be referred to as first and second liquid cooling passages 313 and 315, but as will become more apparent below, first portion 201 may include any suitable configuration and/or number of liquid cooling passages. In some embodiments, first reference plane 329 extending in a second direction transverse to the first direction may extend through central portions of first and second liquid cooling passages 313 and 315. First reference plane 329, according to some implementations, may be arranged such that respective upper surfaces 313a and 315a of first and second liquid cooling passages 313 and 315 are aligned (or substantially aligned) with fifth surface 509, but embodiments are not limited thereto.

First and second liquid cooling passages 313 and 315 may be respective annular passageways encircling axis 512 of first portion 201 when viewed along axis 512, such as shown in FIG. 11. In some implementations, the annular passageways may be partially annular, e.g., C-shaped or otherwise partially encircling axis 512. In some cases, the annular passageways may additionally or alternatively be not truly annular-for example, the annular passageways may have octagonal cross-sections when viewed along axis 512, thus giving rise to annular passageways having radial symmetry instead of axial symmetry. As such, the phrase “annular passageway,” as used herein, may refer to passageways that extend around all or part of axis 512 in a plane perpendicular to axis 512, regardless of the exact shape of such passageways. Thus, the annular passageways may have, for instance, circular, oval, polygonal, or any other suitable cross-sectional geometries when viewed along axis 512. Moreover, the cross-sectional geometries of at least one of the annular passageways may be different from at least one other one of the annular passageways, whether in terms of size, shape, etc.

In some embodiments, first liquid cooling passage 313 may be concentrically (or substantially concentrically) aligned with second liquid cooling passage 315 such that second liquid cooling passage 315 encircles first liquid cooling passage 313. It is also noted that first and second liquid cooling passages 313 and 315 may be fluidically isolated from one another within gas distributor 200, but embodiments are not limited thereto. For example, two or more of the liquid cooling passages, such as first and second liquid cooling passages 313 and 315, of gas distributor 200 may be fluidically connected to one another. To this end, first liquid cooling passage 313 may be fluidically connected to first cooling inlet passages 331A and first cooling outlet passages 331B, and as such, first portion 201 may include first sections 601 of first cooling inlet passages 331A and first sections 603 of first cooling outlet passages 331B.

Second liquid cooling passage 315 may be fluidically connected to second cooling inlet passages 333A and second cooling outlet passages 333B, and as such, first portion 201 may include first sections 605 of second cooling inlet passages 333A and first sections 607 of second cooling outlet passages 333B. First sections 601 and 605 of first and second cooling inlet passages 331A and 333A may respectively include first and second coolant outlet openings 401B and 403B. First sections 603 and 607 of first and second cooling outlet passages 331B and 333B may respectively include first and second coolant inlet openings 401A and 403A. In this manner, liquid coolant 131 may flow into first and second liquid cooling passages 313 and 315 by way of first and second cooling inlet passages 331A and 333A and flow out of first and second liquid cooling passages 313 and 315 by way of first and second cooling outlet passages 331B and 333B.

As seen in FIG. 11, first and second gas distribution ports 511 and 515 may be arranged in respective areas of first portion 201 of gas distributor 200. For instance, first portion 201 may include first area 1101 in which first gas distribution ports 511 are arranged and second area 1103 in which second gas distribution ports 513 are arranged. In some implementations, first area 1101 may be encircled by first liquid cooling passage 313 and second area 1103 may be encircled by second liquid cooling passage 315. First portion 201 may also include third area 1105, which may encircle second liquid cooling passage 315. In this manner, first area 1101, first liquid cooling passage 313, second area 1103, second liquid cooling passage 315, and third area 1105 may be concentrically aligned (or substantially aligned) with one another, but embodiments are not limited thereto. It is also noted that first sections 601 and 605 of first and second cooling inlet passages 331A and 333A and first sections 603 and 607 of first and second cooling outlet passages 331B and 333B are shown in FIG. 11 using phantom lines to demonstrate, for instance, relative positioning of first sections 601, 603, 605, and 607 in relation to first and second liquid cooling passages 313 and 315.

According to some embodiments, first and second gas distribution ports 511 and 513 may be distributed in any suitable arrangement in first and second areas 1101 and 1103. For example, first gas distribution ports 511 may be distributed in first area 1101 in a first multi-ring arrangement and second gas distribution ports 513 may be distributed in second area 1103 in a second multi-ring arrangement. The first and second multi-ring arrangements may be concentrically aligned (or substantially aligned) with first area 1101, first liquid cooling passage 313, second area 1103, second liquid cooling passage 315, and third area 1105, but embodiments are not limited thereto. In some embodiments, one or more of first and second gas distribution ports 511 and 513 may be in (e.g., encircled by respective portions of) one or more of first and second liquid cooling passages 313 and 315. Some examples of such configurations will be described in more detail in association with FIGS. 12, 14, 15, and 16.

Whatever the case, the presence of at least one gas distribution port in a corresponding liquid cooling passage may form, for instance, an impinging surface, restriction, or other obstruction that may not only promote more turbulent flow of liquid coolant 131 through the corresponding liquid cooling passage, but may also increase the velocity of such liquid coolant 131. The increase in turbulence and/or velocity may have concomitant benefits in terms of cooling efficiency, e.g., enhanced rates of heat extraction from gas distributor 200, more uniform temperature profile of gas distributor 200, etc. In some embodiments, additional or alternative forms of impinging surfaces, restrictions, and/or other obstructions, protrusions, tortuous passageways, etc., may be formed in one or more of the liquid cooling passages of gas distributor 200 to increase its thermal performance.

FIGS. 12, 13, 14, 15, and 16 schematically illustrate sectional views of other first portions of a gas distributor according to some embodiments.

As seen in FIG. 12, first portion 1200 may include a single liquid cooling passage, i.e., liquid cooling passage 1201. In some cases, liquid cooling passage 1201 may have a generally circular configuration when viewed along axis 1203, which is shown in FIG. 12 as extending out of the page. Axis 1203 may, in some embodiments, form a central axis of first portion 1200.

Liquid cooling passage 1201 may be encircled by outer region 1205 when viewed along axis 1203. Unlike first portion 201, first portion 1200 may include first and second gas distribution ports 1207 and 1209 that are positioned in (e.g., encircled by respective portions of) liquid cooling passage 1201. Similar to first and second gas distribution ports 511 and 515 of first portion 201, first and second gas distribution ports 1207 and 1209 of first portion 1200 may be distributed in one or more (e.g., first and second) multi-ring arrangements, which may be concentrically aligned (or substantially aligned) with axis 1203. Further, liquid cooling passage 1201 may be fluidically connected to one or more cooling inlet passages and one or more cooling outlet passages. For instance, liquid cooling passage 1201 may receive one or more flows of liquid coolant from three liquid cooling inlet passages 1211 and three liquid cooling outlet passages 1213, but embodiments are not limited thereto. In other words, liquid cooling passage 1201 may be fluidically connected to any suitable number of cooling inlet passages and cooling outlet passages, and the number of cooling inlet passages need not be equivalent to the number of cooling outlet passages. It is also noted that liquid cooling inlet passages 1211 and liquid cooling outlet passages 1213 are depicted in phantom as the sectional view shown in FIG. 12 does not actually intersect with these passages, but the use of phantom lines at least demonstrates, for instance, the relative positioning of these passages vis-a-vis liquid cooling passage 1201. Furthermore, first portion 1200 may include any suitable number and/or arrangement(s) of gas distribution ports.

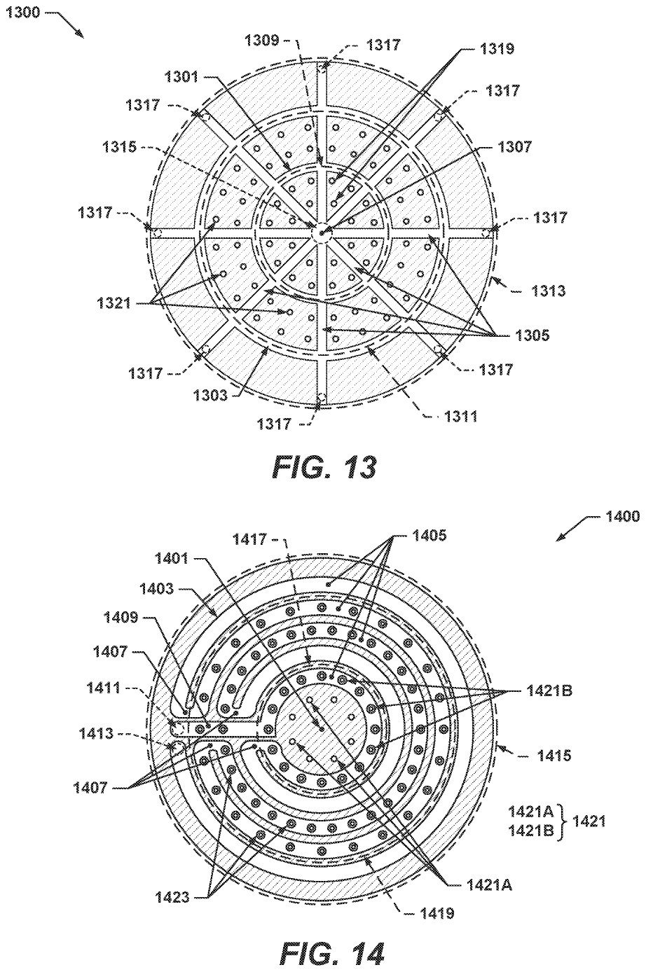

Referring to FIG. 13, first portion 1300 may include a plurality of liquid cooling passages, such as a plurality of annularly configured liquid cooling passages (e.g., first and second liquid cooling passages 1301 and 1303) and a plurality of radially extending liquid cooling passages (e.g., third liquid cooling passages 1305). First and second liquid cooling passages 1301 and 1303 may be concentrically aligned (or substantially aligned) with axis 1307, which is shown in FIG. 13 as extending out of the page. Third liquid cooling passages 1305 may extend radially from axis 1307 and may be fluidically connected to first and second liquid cooling passages 1301 and 1303. Although first portion 1300 is shown as including two annularly configured liquid cooling passages and eight radially extending liquid cooling passages, embodiments are not limited thereto. For example, first portion 1300 may include any suitable number of annularly configured and/or radially extending liquid cooling passages.

According to some embodiments, second liquid cooling passage 1303 may encircle first liquid cooling passage 1303. First liquid cooling passage 1301 may not only encircle first area 1309 of first portion 1300, but may also serve as a boundary between first and second areas 1309 and 1311 of first portion 1300. Similarly, second liquid cooling passage 1303 may not only encircle second area 1311 of first portion 1300, but may also serve as a boundary between second and third areas 1311 and 1313 of first portion 1300. In some cases, first to third areas 1309-1313 of first portion 1300 may be concentrically aligned (or substantially aligned) with axis 1307. It is also noted that the various liquid cooling passages of first portion 1300 may be fluidically connected to common cooling inlet passage 1315 and a plurality of cooling outlet passages 1317. As with liquid cooling inlet passages 1211 and liquid cooling outlet passages 1213, common cooling inlet passage 1315 and cooling outlet passages 1317 are depicted in phantom as the sectional view shown in FIG. 13 does not actually intersect with these passages, but the use of phantom lines at least demonstrates, for instance, the relative positioning of these passages vis-a-vis the various liquid cooling passages of first portion 1300. As shown, common cooling inlet passage 1315 may be concentrically aligned with axis 1307 in a central area of first portion 1300, such as a center (or substantial center) of first area 1309. In this manner, corresponding proximal ends of third liquid cooling passages 1305 may be fluidically connected to common cooling inlet passage 1315. Distal ends of third liquid cooling passages 1305 may be fluidically connected to respective ones of cooling outlet passages 1317, which may be arranged circumferentially about axis 1307 in third area 1313 of first portion 1300. In this manner, liquid coolant 131 may flow into the various liquid cooling passages of first portion 1200 by way of common cooling inlet passage 1315 and flow out of the various liquid cooling passages of first portion 1200 by way of cooling outlet passages 1317.

Similar to first portion 201, first portion 1300 may include first and second gas distribution ports 1319 and 1321 that are distributed in one or more (e.g., first and second) multi-ring arrangements, which may be concentrically aligned (or substantially aligned) with axis 1307. For example, first gas distribution ports 1319 may be distributed in a first multi-ring arrangement in first area 1309 of first portion 1300, and second gas distribution ports 1321 may be distributed in a second multi-ring arrangement in second area 1311 of first portion 1300. It is noted, however, that first portion 1300 may include any suitable number and/or arrangement(s) of gas distribution ports.

With respect to FIG. 14, first portion 1400 may include one or more liquid cooling passages having a serpentine configuration when viewed along axis 1401, which is shown extending out of the page. For instance, first portion 1400 may include liquid cooling passage 1403 having a serpentine configuration about axis 1401. As used herein, a passage having a serpentine configuration refers to a passage that follows a generally serpentine path, e.g., a path that follows a winding or meandering course, such as, for example, a path that includes a plurality of parallel/straight or concentric/curved longer segments extending between two regions, with the end of each such longer segment generally connected, by a shorter segment, with the closest end or one of the two closest ends of another such longer segment (except for the start and end of such a path, which may not feature such shorter segments). For example, liquid cooling passage 1403 may include a plurality of concentric/curved longer segments 1405 fluidically connected to one another by corresponding shorter segments of a plurality of shorter segments 1407 that flank opposing sides of an inlet segment 1409. Although first portion 1400 is shown including five longer segments 1405 and four shorter segments 1407, embodiments are not limited thereto. For instance, any suitable number of longer segments and/or shorter segments may be utilized to achieve a desired amount of cooling.

According to some embodiments, a proximal end of liquid cooling passage 1403, e.g., a proximal end of inlet segment 1409, may be fluidically connected to cooling inlet passage 1411 and a distal end of liquid cooling passage 1403 may be fluidically connected to cooling outlet passage 1413. Cooling inlet passage 1411 and cooling outlet passage 1413 are depicted in phantom as the sectional view shown in FIG. 14 does not actually intersect with these passages, but the use of phantom lines at least demonstrates an example of the relative positioning that may be utilized for these passages vis-a-vis liquid cooling passage 1403. In this manner, liquid coolant (e.g., liquid coolant 131) may flow into liquid cooling passage 1403 by way of cooling inlet passage 1411, which may be arranged in outer, annular region 1415 of first portion 1400, and flow along inlet segment 1409 into inner, circular region 1417, which may be spaced apart from outer, annular region 1415 by intermediate, annular region 1419. In some embodiments, regions 1415, 1417, and 1419 may be concentrically aligned (or substantially aligned) with one another. From inner, circular region 1417, the liquid coolant may flow along the serpentine path provided by segments 1405 and 1407 of liquid cooling passage 1403 to provide a flow liquid coolant in each of regions 1415, 1417, and 1419. The flow of liquid coolant may exit first portion 1400 via cooling outlet passage 1413, which may also be arranged in outer, annular region 1415.

Similar to first portion 201, first portion 1400 may include first and second gas distribution ports 1421 and 1423 that are distributed in one or more (e.g., first and second) multi-ring arrangements, which may be concentrically aligned (or substantially aligned) with axis 1401. For example, first gas distribution ports 1421 may be distributed in a first multi-ring arrangement in inner, circular region 1417 of first portion 1400, and second gas distribution ports 1423 may be distributed in a second multi-ring arrangement in intermediate, annular region 1419. First gas distribution ports 1421 may include one or more first gas distribution ports 1421A arranged in an area outside of liquid cooling passage 1403 and one or more first gas distribution ports 1421B arranged in an area inside of liquid cooling passage 1403. First gas distribution ports 1421B may, in some cases, encircle first gas distribution ports 1421A. Second gas distribution ports 1423 may be arranged in areas inside of liquid cooling passage 1403. It is noted, however, that first portion 1400 may include any suitable number and/or arrangement(s) of gas distribution ports.

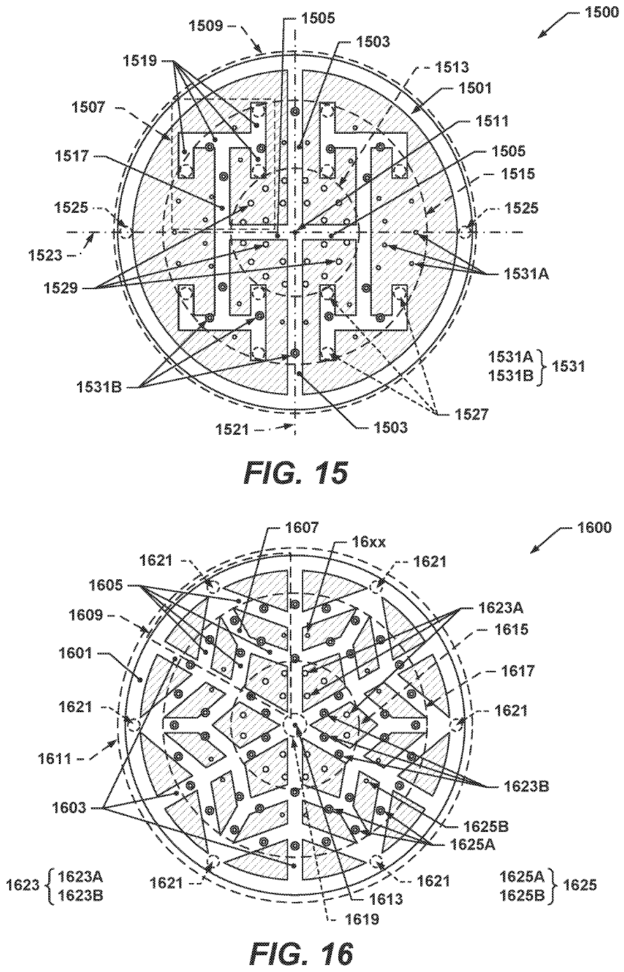

According to some embodiments, the one or more liquid cooling passages of first portion 201 may have any suitable fractal pattern, two examples of which will be described in more detail in association with FIGS. 15 and 16.

Referring to FIG. 15, first portion 1500 may include a plurality of liquid cooling passages, such as annular cooling passage 1501, first radial cooling passages 1503, second radial cooling passages 1505, and a plurality of cooling passage patterns, e.g., cooling passage pattern 1507. Hereinafter, cooling passage patterns will be collectively or individually referred to as cooling passage pattern(s) 1507. In some embodiments, annular cooling passage 1501 may be formed in outer, annular region 1509 of first portion 1500, which may have central (or center) axis 1511 extending out of the page. Outer, annular region 1509 may encircle inner, circular region 1513, which may be spaced apart from outer, annular region 1509 by intermediate, annular region 1515. Regions 1509, 1513, and 1515 of first portion 1500 may, in some implementations, be concentrically aligned (or substantially aligned) with one another.

Proximal ends of first and second radial cooling passages 1503 and 1505 may extend radially from central axis 1511, and may be fluidically connected to one another within inner, circular region 1513. Distal ends of first radial cooling passages 1503 may be fluidically connected to corresponding portions of annular cooling passage 1501 in outer, annular region 1509, and distal ends of second radial cooling passages 1505 may be fluidically connected one or more cooling passage patterns among cooling passage patterns 1507. In the depicted example, distal ends of second radial cooling passages 1505 are each connected to two cooling passage patterns among cooling passage patterns 1507.

According to some embodiments, each cooling passage pattern 1507 may include a corresponding first branch passage 1517 fluidically connecting a second radial cooling passage among second radial cooling passages 1505 to respective pluralities of second branch passages 1519, which may form repeating patterns of cooling passages within regions 1509 and 1513 of first portion 1500. In some cases, the configuration of the repeating pattern of cooling passages formed by a first group of second branch passages 1519 associated with one first branch passage 1517 may be symmetrical to the configuration of the repeating pattern of cooling passages formed by a second group of second branch passages 1519 associated with another first branch passage 1517 about one or more axes of symmetry, such as axes 1521 and 1523. In this manner, the conjunction of annular cooling passage 1501, first radial cooling passages 1503, second radial cooling passages 1505, and the plurality of cooling passage patterns, e.g., cooling passage pattern 1507, may exhibit two-fold symmetry.

In some implementations, annular cooling passage 1501 may be fluidically connected to one or more cooling inlet passages, such as cooling inlet passages 1525, which may be arranged on diametrically opposing sides of first portion 1500. For example, cooling inlet passages 1525 may be arranged on diametrically opposing sides of first portion 1500 and axis 1523 may extend through central portions of each of cooling inlet passages 1525, and in some cases, also extend through central portions of second radial cooling passages 1505. In those cases in which the conjunction of annular cooling passage 1501, first radial cooling passages 1503, second radial cooling passages 1505, and the plurality of cooling passage patterns, e.g., cooling passage pattern 1507, exhibit two-fold symmetry, axis 1521 may extend through central portions of first radial cooling passages 1503. It is also noted that distal ends of second branch passages 1519 may be fluidically connected to corresponding cooling outlet passages, such as cooling outlet passages 1527. Cooling inlet passages 1525 and cooling outlet passages 1527 are depicted in phantom as the sectional view shown in FIG. 15 does not actually intersect with these passages, but the use of phantom lines at least demonstrates an example of their relative positioning vis-a-vis areas of first portion 1500.

Liquid coolant (e.g., liquid coolant 131) may flow into the plurality of liquid cooling passages of first portion 1500 by way of cooling inlet passages 1525 and may flow circumferentially about outer, annular region 1509 to the distal ends of first radial cooling passages 1503. In this manner, the liquid coolant may flow radially inwards along first radial cooling passages 1503 and, thereby, through regions 1509, 1513, and 1515 to proximal ends of second radial cooling passages 1505. The liquid coolant may then flow radially outwards along second radial cooling passages 1505 from inner, circular region 1513 to intermediate, annular region 1515, and may be distributed to respective cooling passage patterns 1507. The flow of liquid coolant may flow through cooling passage patterns 1507 and exit first portion 1500 via the cooling outlet passages (e.g., cooling outlet passages 1527) fluidically connected to distal ends of second branch passages 1519.

Similar to first portion 201, first portion 1500 may include first and second gas distribution ports 1529 and 1531 that are distributed in one or more (e.g., first and second) multi-ring arrangements, which may be concentrically aligned (or substantially aligned) with axis 1511. For example, first gas distribution ports 1529 may be distributed in a first multi-ring arrangement in inner, circular region 1513 of first portion 1500, and second gas distribution ports 1531 may be distributed in a second multi-ring arrangement in intermediate, annular region 1515. Second gas distribution ports 1531 may include one or more first gas distribution ports 1531A arranged in an area outside of the various liquid cooling passages of first portion 1500 and one or more second gas distribution ports 1531B arranged in an area inside of at least one liquid cooling passage of first portion 1500. In some cases, second gas distribution ports 1531A may be arranged in one or more of the various rings of gas distribution ports forming the second multi-ring arrangement of second gas distribution ports 1531. The same may be true with respect to second gas distribution ports 1531B. First gas distribution ports 1529 may be arranged in areas outside of the various liquid cooling passages of first portion 1500. In some cases, the arrangement of first and second gas distribution ports 1529 and 1531 may also exhibit two-fold symmetry relative to axes 1521 and 1523. It is noted, however, that first portion 1500 may include any suitable number and/or arrangement(s) of gas distribution ports.

Adverting to FIG. 16, first portion 1600 may include a plurality of liquid cooling passages, such as annular cooling passage 1601, radial cooling passages 1603, first branch passages 1605, and second branch passages 1607, that together form a plurality of repeat cooling passage patterns 1609. In some embodiments, the plurality of repeat cooling passage patterns 1609 may form a snowflake-like fractal pattern of liquid cooling passages. In some cases, annular cooling passage 1601 may be formed in outer, annular region 1611 of first portion 1600, which may have central (or center) axis 1613 extending out of the page. Outer, annular region 1611 may encircle inner, circular region 1615, which may be spaced apart from outer, annular region 1611 by intermediate, annular region 1617. Regions 1611, 1615, and 1617 of first portion 1600 may, in some implementations, be concentrically aligned (or substantially aligned) with one another. Proximal ends radial cooling passages 1603 may extend radially from central axis 1613, and may be fluidically connected to one another within inner, circular region 1615. Distal ends of radial cooling passages 1603 may be fluidically connected to corresponding portions of annular cooling passage 1601 in outer, annular region 1611. Each radial cooling passage among radial cooling passages 1603 may have a plurality of first branch passages among first branch passages 1605 fluidically connected thereto at various intermediate locations between inner, circular region 1615 and outer, annular region 1611. For instance, proximal ends of first pairs of first branch passages 1605 may extend in a first oblique direction from first and second intermediate locations of corresponding radial cooling passages 1603, and proximal ends of second pairs of first branch passages 1605 may extend in a second oblique direction from the first and second intermediate locations of corresponding radial cooling passages 1603. It is noted that the second oblique direction may be different from the first oblique direction. Further, each cooling passage pattern among cooling passage patterns 1609 may include a second branch passage among second branch passages 1607 that fluidically connects the distal ends of those first branch passages among first branch passages 1605 forming a portion of that cooling passage pattern. In some cases, distal ends of radially outermost first branch portions among first branch passages 1605 may also be fluidically connected to corresponding portions of annular cooling passage 1601. With this configuration, the snowflake-like fractal pattern formed by the various liquid cooling passages of first portion 1600 may exhibit multi-fold symmetry (e.g., three-fold symmetry) with respect to folding axes extending along, for example, radial cooling passages 1603.

In some implementations, proximal ends of radial cooling passages 1603 may be fluidically connected to common cooling inlet passage 1619, which may be concentrically aligned (or substantially aligned) with axis 1613 and may be arranged within inner, circular region 1615. Further, a plurality of cooling outlet passages 1621 may be fluidically connected to annular cooling passage 1601 in areas arranged within outer, annular region 1611. In some embodiments, cooling outlet passages 1621 may be circumferentially arranged about axis 1613 with each cooling passage pattern among cooling passage patterns 1609 being associated with a respective cooling outlet passage among cooling outlet passages 1621. To this end, cooling outlet passages 1621 may be circumferentially arranged between the distal ends of adjacent radial cooling passages among radial cooling passages 1603. In some cases, respective cooling outlet passages 1621 may be radially aligned (or substantially aligned) with corresponding second branch passages 1607 of respective cooling passage patterns 1609. It is also noted that cooling inlet passage 1619 and cooling outlet passages 16121are depicted in phantom as the sectional view shown in FIG. 16 does not actually intersect with these passages, but the use of phantom lines at least demonstrates an example of the relative positioning that may be utilized for these passages vis-a-vis areas of first portion 1600.

According to some embodiments, liquid coolant (e.g., liquid coolant 131) may flow into the plurality of liquid cooling passages of first portion 1600 by way of common cooling inlet passage 1619 and may flow outwards in a substantially radial flow pattern from inner, circular region 1615 through intermediate, annular region 1617 and to outer, annular region 1611 via the conjunction of radial cooling passages 1603, first branch passages 1605, and second branch passages 1607. It is noted, however, that some of the substantially radial flow of the liquid coolant may be distributed in intermediate, annular region 1617 by way of first and second branch passages 1605 and 1607, and some of the substantially radial flow of the liquid coolant may flow radially into and be circumferentially distributed in outer, annular region 1611 from distal ends of radial cooling passages 1603 via corresponding portions of annular cooling passage 1601. The liquid coolant distributed in intermediate, annular region 1617 may also flow into annular cooling passage 1601 via second branch passage 1607 and the distal ends of the radially outermost pairs of the first branch passages 1605 associated with each cooling passage pattern 1609. In this manner, the liquid coolant flowing into annular cooling passage 1601 may exit first portion 1600 via the cooling outlet passages 1621.

Similar to first portions 1400 and 1500, first portion 1600 may include first and second gas distribution ports 1623 and 1625 that are distributed in one or more (e.g., first and second) multi-ring arrangements, which may be concentrically aligned (or substantially aligned) with axis 1613. For example, first gas distribution ports 1623 may be distributed in a first multi-ring arrangement in inner, circular region 1615 of first portion 1600, and second gas distribution ports 1625 may be distributed in a second multi-ring arrangement in intermediate, annular region 1617. First gas distribution ports 1623 may include one or more first gas distribution ports 1623A arranged in an area outside of the various liquid cooling passages of first portion 1600 and one or more first gas distribution ports 1623B arranged in an area inside of at least one liquid cooling passage of first portion 1600. To this end, first gas distribution ports 1623A may be arranged in one or more of the various rings of first gas distribution ports forming the first multi-ring arrangement of first gas distribution ports 1623. In a similar fashion, second gas distribution ports 1625 may include one or more second gas distribution ports 1625A arranged in an area outside of the various liquid cooling passages of first portion 1600 and one or more second gas distribution ports 1625B arranged in an area inside of at least one liquid cooling passage of first portion 1600. In some cases, second gas distribution ports 1625A may be arranged in one or more of the various rings of second gas distribution ports forming the second multi-ring arrangement of second gas distribution ports 1625. In some cases, the arrangement of first and second gas distribution ports 1623 and 1625 may also exhibit multi-fold symmetry (e.g., three-fold symmetry) with respect to folding axes extending along, for example, radial cooling passages 1603. That being said, first portion 1600 may include any suitable number and/or arrangement(s) of gas distribution ports.

### Example Second Portions

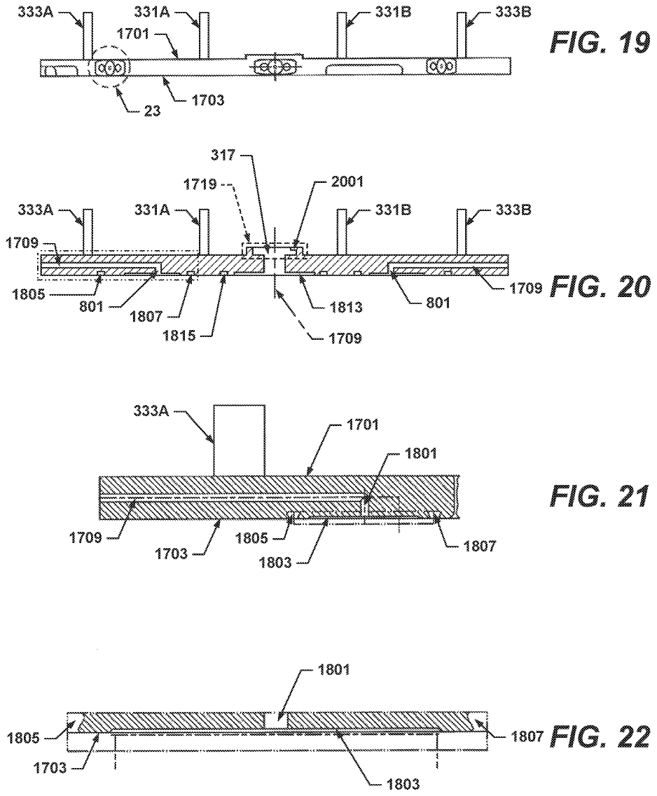

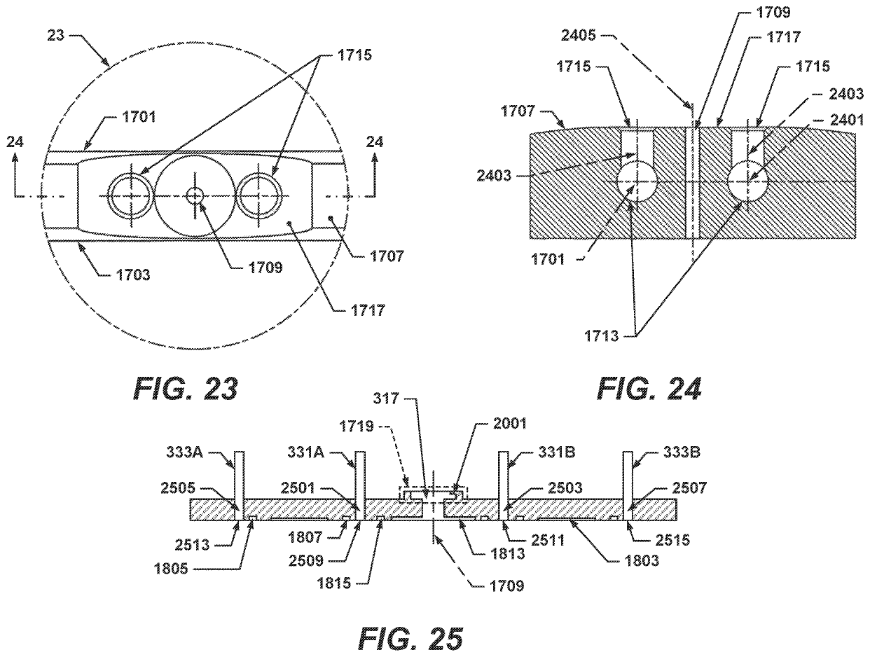

FIGS. 17 and 18 schematically illustrate perspective views of a second portion of the gas distributor of FIG. 2 according to some embodiments. FIG. 19 schematically illustrates an orthographic view of the second portion of the gas distributor of FIG. 2 according to some embodiments. FIG. 20 schematically illustrates a cross-sectional view of the second portion of the gas distributor of FIG. 2 according to some embodiments. FIG. 21 schematically illustrates an enlarged detail view of portion 21 depicted in FIG. 20 according to some embodiments. FIG. 22 schematically illustrates an enlarged detail view of portion 22 depicted in FIG. 21 according to some embodiments. FIG. 23 schematically illustrates an enlarged detail view of portion 23 depicted in FIG. 19 according to some embodiments. FIG. 24 schematically illustrates a cross-sectional view of the second portion of the gas distributor of FIG. 2 taken along sectional line 24-24 according to some embodiments. FIG. 25 schematically illustrates a cross-sectional view of the second portion of the gas distributor according to some embodiments.

With reference to FIGS. 17-24, second portion 203 may have a generally annular configuration including first (e.g., upper) surface 1701, second (e.g., lower) surface 1703, third (e.g., inner) surface 1705, and fourth (e.g., outer) surface 1707. First surface 1701 may correspond to second surface 303 of gas distributor 200. A plurality of radially extending gas passages 1709 may extend inwardly from fourth surface 1707 toward axis 1711, and a plurality of axially extending gas passages 1801 may extend from second surface 1703 toward first surface 1701 in an axial direction parallel (or substantially parallel) to axis 1711. In some cases, axis 1711 may form a center or central axis of second portion 203 and/or gas distributor 200.

Although eight radially extending gas passages 1709 and eight gas passages 1801 are shown as an example, embodiments are not limited thereto. For instance, second portion 203 may include more or less than eight radially extending gas passages 1709 and/or more or less than eight gas passages 1801. For descriptive convenience, it will be assumed that second portion 203 includes eight radially extending gas passages 1709 and eight gas passages 1801.

Proximal ends of s may be fluidically connected to radially extending gas passages 1709 and distal ends of gas passages 1801 may be fluidically connected to first recessed portion 1803 formed in second surface 1703. First recessed portion 1803 may define second gas distribution plenum 307 in gas distributor 200 in conjunction with second surface 503 of first portion 201. Second gas distribution plenum 307 may have a generally annular configuration when viewed along axis 1711 and may be laterally sealed between first and second gaskets (e.g., O-rings) 609 and 611 (shown in phantom in FIG. 6), which may be at least partially supported in second and third recesses 1805 and 1807 in second surface 1703. In some cases, when first and second portions 201 and 203 are combined to form gas distributor 200, first and second gaskets 609 and 611 at least partially supported in second and third recesses 1805 and 1807 may be at least partially compressed between respective second surfaces 1703 and 503 of second and first portions 203 and 201.

Third surface 1705 of second portion 203 may define an outer boundary of first gas inlet 317, which may have a generally cylindrical configuration extending along axis 1711 from first surface 1701 to second surface 1703. A proximal end of first gas inlet 317 may be configured to receive one or more gases (e.g., one or more process gases) from, for example, gas delivery system 147 and a distal end of first gas inlet 317 may be fluidically connected to first gas distribution plenum 305. In some cases, first gas distribution plenum 305 may have a generally cylindrical configuration when viewed along axis 1711 and may be defined by the conjunction of fourth recess 1813 in second surface 1703 and second surface 503 of first portion 201. To this end, first gas distribution plenum 305 may be fluidically isolated from second gas distribution plenum 307 within gas distributor 200 by third gasket (e.g., an O-ring) 613 (shown in phantom in FIG. 6), which may be at least partially supported in fifth recess 1815 in second surface 1703 of second portion 203. In some cases, when first and second portions 201 and 203 are combined to form gas distributor 200, third gasket 613 may be at least partially compressed between respective second surfaces 1703 and 503 of second and first portions 203 and 201.

To supply one or more gases (e.g., process gas(es)) to radially extending gas passages 1709, second portion 203 may include first and second mounting holes 1713 and 1715 for coupling (e.g., detachably coupling) respective gas connection mounting blocks 209 thereto.

For instance, second portion 203 may include eight pairs of axially extending mounting holes (e.g., first mounting holes 1713) and eight pairs of radially extending mounting holes (e.g., second mounting holes 1715). In this manner, each gas passage 1709 may be associated with a corresponding pair of first mounting holes 1713 and a respective pair of second mounting holes 1715. First mounting holes 1713 may extend through second portion 203 along respective central axes 2401, e.g., each of first mounting holes 1713 may extend from first surface 1701 through second surface 1703 along a corresponding central axis 2401, which is illustrated in FIG. 24 as extending out of the page. Each pair of second mounting holes 1715 may be arranged in correspondence with a respective mounting surface, such as mounting surface 1717, which may form a respective planar (or substantially planar) surface in fourth surface 1707. As such, second portion 203 may include eight mounting surfaces 1717 in fourth surface 1707 that are circumferentially arranged about axis 1711 in association with corresponding radially extending gas passages 1709. Corresponding central axes 2403 of respective second mounting holes 1715 may extend radially inwards towards axis 1711 and may intersect with a corresponding one of central axes 2401. In this manner, each second mounting hole among second mounting holes 1715 may be fluidically connected to a corresponding first mounting hole among first mounting holes 1713, such as shown in FIG. 24, but embodiments are not limited thereto. To this end, respective pairs of first and second mounting holes 1713 and 2415 may be spaced evenly (or substantially evenly) from corresponding central axes 2405 of radially extending gas passages 1709.

In some implementations, the supply of one or more gases (e.g., process gas(es)) to first gas inlet 317 may be facilitated using annular protrusion 1719, which may extend from first surface 1701 of second portion 203 along axis 1711. Annular protrusion 1719 may be configured to not only structurally mate with, for instance, a gas supply stem (or other structure) fluidically connected to, for instance, gas delivery system 147, but may also fluidically connect to first gas inlet 317. In some cases, annular protrusion 1719 may also include one or more mating engagement features, such as a bayonet-type engagement feature 2001, that are configured to interlock with one or more corresponding mating engagement features of the gas supply stem. It is contemplated, however, that any other suitable mating engagement features may be utilized, such as for example, one or more fasteners, adhesives, other mating engagement structures, welds, and/or the like.

According to various embodiments, second portion 203 may further include second sections 2501 of first cooling inlet passages 331A and second sections 2503 of first cooling outlet passages 331B. Second portion 203 may also include second sections 2505 of second cooling inlet passages 333A and second sections 2507 of second cooling outlet passages 333B. When first and second portions 201 and 203 are incorporated as part of gas distributor 200, distal ends 2509 of second sections 2501 may be fluidically connected to first sections 601 formed in first portion 201, distal ends 2511 of second sections 2503 may be fluidically connected to first sections 603 in first portion 201, distal ends 2513 of second sections 2505 may be fluidically connected to first sections 605 in first portion 201, and distal ends 2515 of second sections 2507 may be fluidically connected to first sections 607 in first portion 201. In this manner, liquid coolant 131 may flow into first and second liquid cooling passages 313 and 315 in first portion 201 by way of first and second cooling inlet passages 331A and 333A and flow out of first and second liquid cooling passages 313 and 315 in first portion 201 by way of first and second cooling outlet passages 331B and 333B.

According to some embodiments, at least one of first and second portions 201 and 203 may be fabricated by, for example, machining or otherwise forming their various features from one or more pieces or layers of material. For instance, as seen in FIGS. 7, 8, 20, and 25 the various features of first and second portions 201 and 203 may be formed in respective single pieces or bodies of material. In FIGS. 9, 10, 26, and 27, first and second portions 201 and 203 may be fabricated by, for instance, machining or otherwise forming their various features using multiple discrete layers and then bonding, fusing, or otherwise mating the various layers together into a laminated or otherwise coupled stack to provide first and second portions 201 and 203. It is contemplated, however, that other suitable techniques may be used to produce equivalent structures, e.g., additive manufacturing may be used to “3D print” at least one of first and second portions 201 and 203 from, for example, metal, ceramic, and/or any other suitable material(s). Examples of multiple discrete layers forming first and second portions 201 and 203 will be described in more detail in association with FIGS. 9, 10, 26, and 27.

FIGS. 9 and 10 schematically illustrate cross-sectional views of a first portion of a gas distributor according to some embodiments.

Referring to FIGS. 9 and 10, first portion 201 may be formed as first portion 900 including initially discrete layers 901 and 903. Layer 901 may define second surface 503 and include mating surface 905, and layer 903 may define first surface 501 and include mating surface 907. In this manner, features such as first and second liquid cooling passages 313 and 315, may be formed as corresponding recesses in mating surface 907 of layer 903 versus enclosed cavities as in the case of a single piece or body of material structure. When joined to form first portion 900, mating surfaces 905 and 907 may be bonded, fused, or otherwise joined together, and mating surface 905 may at least partially enclose, for instance, first and second liquid cooling passages 313 and 315 within first portion 900. This may simplify and/or reduce the costs of manufacturing first portion 201. That said, it may increase the complexity of aligning portions of features spanning across different layers, such as first and second gas distribution ports 511 and 515.

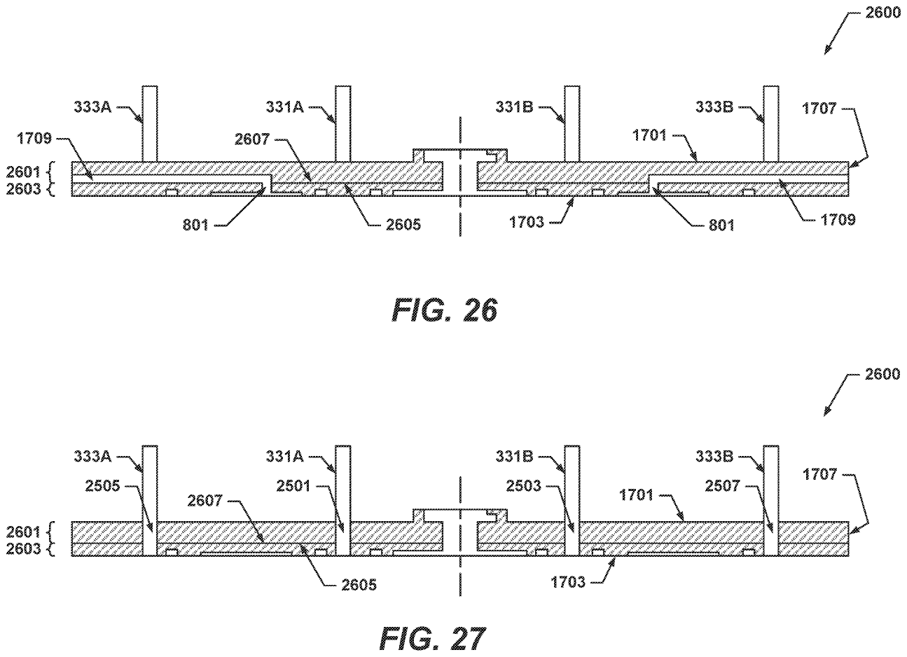

FIGS. 26 and 27 schematically illustrate cross-sectional views of a second portion of a gas distributor according to some embodiments.

With reference to FIGS. 26 and 27, second portion 203 may be formed as second portion 2600 including initially discrete layers 2601 and 2603. Layer 2601 may define first surface 1701 and include mating surface 2605, and layer 2603 may define second surface 1703 and include mating surface 2607. In this manner, features such as radially extending gas passages 1709 may be formed as corresponding recesses in mating surface 2605 of layer 2601 having relatively lower aspect ratios versus relatively higher aspect ratio blind bores formed in fourth surface 1707 of a single piece or body of material structure. When joined to form section portion 2600, mating surfaces 2605 and 2607 may be bonded, fused, or otherwise joined together, and mating surface 2607 may at least partially enclose, for instance, radially extending gas passages 1709 within second portion 2600. This may simplify and/or reduce the costs of manufacturing second portion 203. That being said, it may increase the complexity of aligning portions of features spanning across different layers of second portion 2600, such as second sections 2501 and 2503 of first cooling inlet passage 331A and first cooling outlet and 331B and second sections 2505 and 2507 of second cooling inlet passage 333A and second cooling outlet passage and 333B.

### Example Third Portions

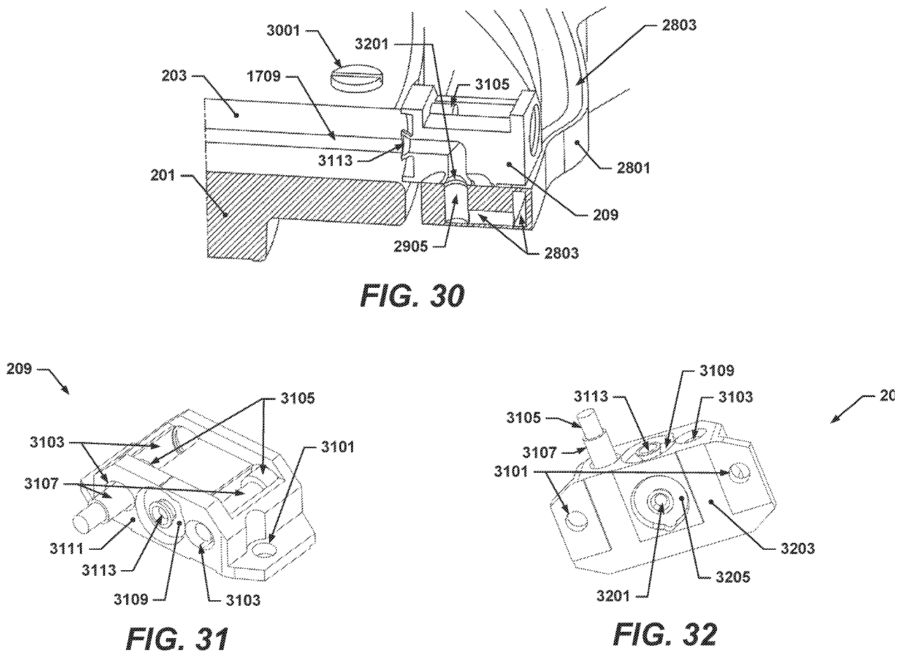

FIG. 28 schematically illustrates an orthographic view of a ring assembly of the gas distributor of FIG. 2 according to some embodiments. FIG. 29 schematically illustrates a perspective view of a ring structure of the ring assembly of FIG. 28 according to some embodiments. FIG. 30 schematically illustrates a cross-sectional view of a portion of the gas distributor of FIG. 2 according to some embodiments. FIGS. 31 and 32 schematically illustrate various perspective views of a connection block of the gas ring assembly of FIG. 28 according to some embodiments.

Referring to FIGS. 28-32, third portion 205 of gas distributor 200 may define a gas delivery structure having a plurality of gas connection mounting blocks (or blocks) 209 coupled to respective mounting locations 2901 on (or in) support ring 2801. Blocks 209 may be fluidically connected between gas delivery system 147 and corresponding radially extending gas passages 1709 in second portion 203 of gas distributor 200. In this manner, the number of blocks 209 may correspond to the number of radially extending gas passages 1709, but embodiments are not limited thereto. However, for descriptive convenience, it will be assumed that the number of blocks 209 corresponds to the number of radially extending gas passages 1709. As shown, the number of blocks 209 is eight.

According to various embodiments, blocks 209 may be coupled to corresponding mounting locations 2901, which may be circumferentially distributed about support ring 2801 in correspondence with the locations of radially extending gas passages 1709. In some cases, blocks 209 may be coupled to corresponding mounting locations 2901 via a plurality of fasteners interfacing with respective mounting points 2903 in respective mounting locations 2901 and corresponding mounting bores 3101 in corresponding blocks 209. Blocks 209 may be fluidically connected to one another via a plurality of connecting passages 2803, which may be supplied with one or more gases via gas supply inlet 2905 formed in inlet section 2805 of support ring 2801. In some implementations, support ring 2801 may include a plurality of gas supply outlets 2907, which may also be fluidically connected to one another by connecting passages 2803.

With additional reference to FIG. 17, each block among blocks 209 may include a corresponding mounting surface 3203, which contacts a respective mounting surface 2909 at corresponding mounting locations 2901 of support ring 2801 such that corresponding gas supply outlets 2907 align (or substantially align) with corresponding radially extending gas passages 1709 in second portion 203 when gas distributor 200 is being assembled. To this end, respective mounting bores 3103 of blocks 209 may be aligned (or substantially aligned) with corresponding second mounting holes 1715 in mounting surface 1717 of second portion 203.

This may enable fasteners (e.g., shoulder screws) 3105 slidably engaged in mounting bores 3103 to engage with second mounting holes 1715 in second portion 203. In some cases, fasteners 3001 may not only engage with first mounting holes 1713 in second portion 203, but also interface with (e.g., abut against) respective sacrificial sleeves 3107 fit (e.g., press-fit) on corresponding fasteners 3105 to form even more stable connections between blocks 209 and second portion 203. Grooves 3109 in each surface 3111 of respective blocks 209 may encircle corresponding outlet ports 3113 in blocks 209. In this manner, gaskets (e.g., O-rings) may be at least partially supported in grooves 3109 and at least partially compressed between blocks 209 and respective mounting surfaces 1717 in second portion 203 to provide seals between blocks 209 and second portion 203 in an assembled state of gas distributor 200. Corresponding grooves 3205 in respective mounting surfaces 3203 of blocks 209 may encircle corresponding input ports 3201 of blocks 209 to enable respective gaskets to be at least partially supported therein and at least partially compressed between blocks 209 and respective mounting surfaces 2909 of support ring 2801 in an assembled state of third portion 205. This may provide seals between blocks 209 and support ring 2801. Accordingly, gas(es) input to gas supply inlet 2905 of support ring 2801 may flow into connecting passages 2803 and out of gas supply outlets 2907 to feed respective input ports 3201 in blocks 209 with a portion of the gas(es). The gas(es) may flow out of corresponding outlet ports 3113 in blocks 209 and into respective radially extending gas passages 1709 in second portion 203.

Some Modifications to the Example First, Second, and/or Third Portions

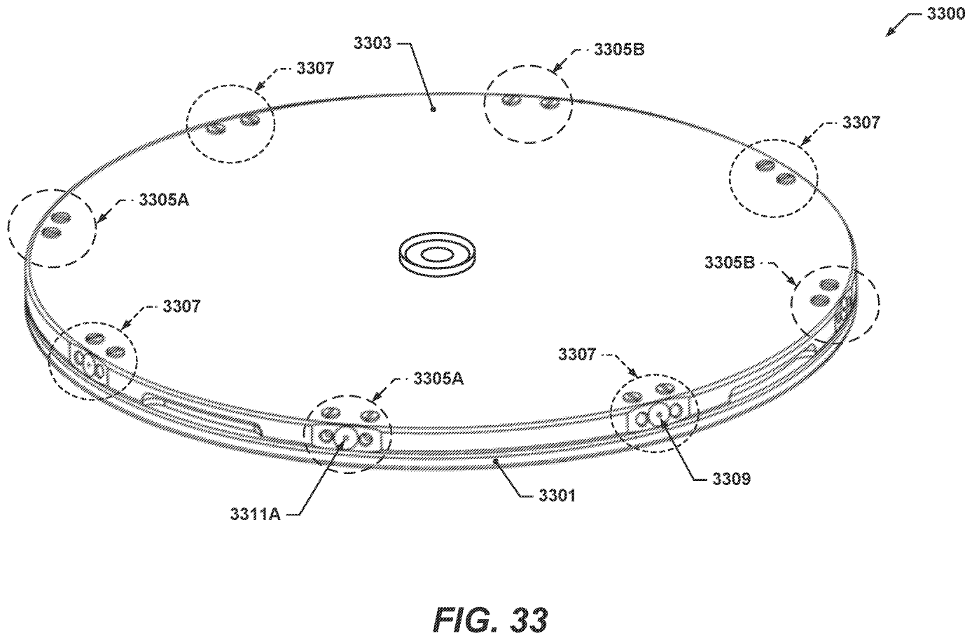

In some implementations, a gas distributor may be modified to enable alternative input and output of liquid coolant to and from its liquid cooling passage(s). Some examples of such gas distributors will be described in more detail in association with FIGS. 33-36.

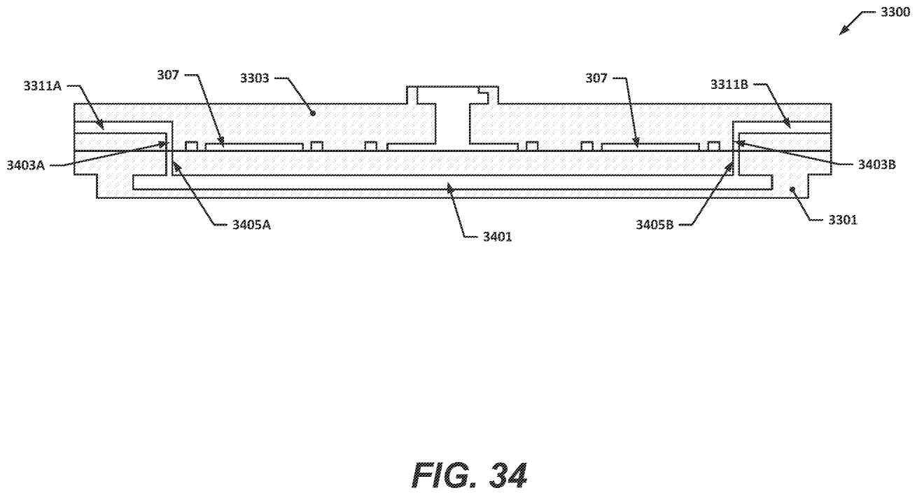

FIG. 33 schematically illustrates a perspective view of a gas distributor in a partially assembled state according to some embodiments. FIG. 34 schematically illustrates a cross-sectional view of the gas distributor of FIG. 33 in the partially assembled state according to some embodiments. It is noted that gas distributor 3300 that will be described in conjunction with FIGS. 33 and 34 may be similar to gas distributor 200 described in association with FIGS. 2-32, and as such, primarily differences will be described below.

Referring to FIGS. 33 and 34, gas distributor 3300 may at least include first and second portions 3301 and 3303 that may be configured similar to first and second portions 201 and 203 of gas distributor 200, however, first and second portions 3301 and 3303 may be configured to allow for radial input and output of liquid coolant 131 via coolant inlet and outlet areas 3305A and 3305B in second portion 3303 and radial input of one or more gases via gas inlet areas 3307 in second portion 3303. In some embodiments, coolant inlet and outlet areas 3305A and 3305B may be alternately arranged with gas inlet areas 3307 about a circumferential area of second portion 3303. Gas inlet areas 3307 may include radially extending gas passages 3309 configured similar to radially extending gas passages 1709, and thereby, configured to supply input gas(es) to second gas distribution plenum 307 in a similar fashion as described in association with gas distributor 200. It is noted, however, that coolant inlet and outlet areas 3305A and 3305B may respectively include radially extending liquid coolant inlet and outlet passages 3311A and 3311B that are fluidically connected to liquid cooling passage 3401, which may be configured similar to liquid cooling passage 1201 described in conjunction with FIG. 12. In this manner, gas distributor 3300 may omit first and second cooling inlet passages 331A and 333A and first and second cooling outlet passages 331B and 333B, as well as the sections of first and second cooling inlet passages 331A and 333A and the sections of first and second cooling outlet passages 331B and 333B formed in first and second portions 201 and 203.

According to various embodiments, radially extending liquid coolant inlet and outlet passages 3311A and 3311B may be configured similar to radially extending gas passages 1709 of gas distributor 200, except radially extending liquid coolant inlet and outlet passages 3311A and 3311B may be fluidically connected to first liquid coolant outlets and inlets 3403B and 3403A in second portion 3303. First liquid coolant outlets and inlets 3403B and 3403A may extend in an axial direction and may be fluidically connected to second liquid coolant inlets and outlets 3405A and 3405B in first portion 201. Second liquid coolant inlets and outlets 3405A and 3405B may also extend in the axial direction and may be fluidically connected to liquid cooling passage 3401. In this manner, liquid coolant 131 may flow into liquid cooling passage 3401 in first portion 3301 by way of radially extending liquid coolant inlet passages 3311A, first liquid coolant outlets 3403B, and second liquid coolant inlets 3405A. Similarly, liquid coolant 131 may flow out of liquid cooling passage 3401 in first portion 3301 by way of second liquid coolant outlets 3405B, first liquid coolant inlets 3403A, and radially extending liquid coolant outlet passages 3311B. A remainder of gas distributor 3300 may be configured substantially similar to gas distributor 200, except those connection blocks fluidically connected to coolant inlet and outlet areas 3305A and 3305B may be configured to flow liquid coolant 131 versus one or more gases utilized before, during, and/or after at least one semiconductor processing stage.

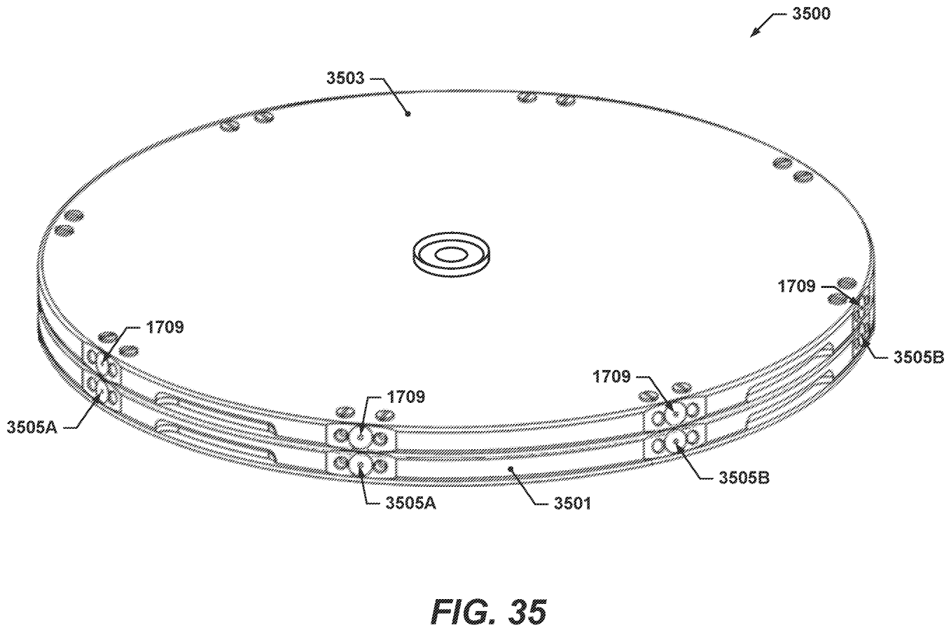

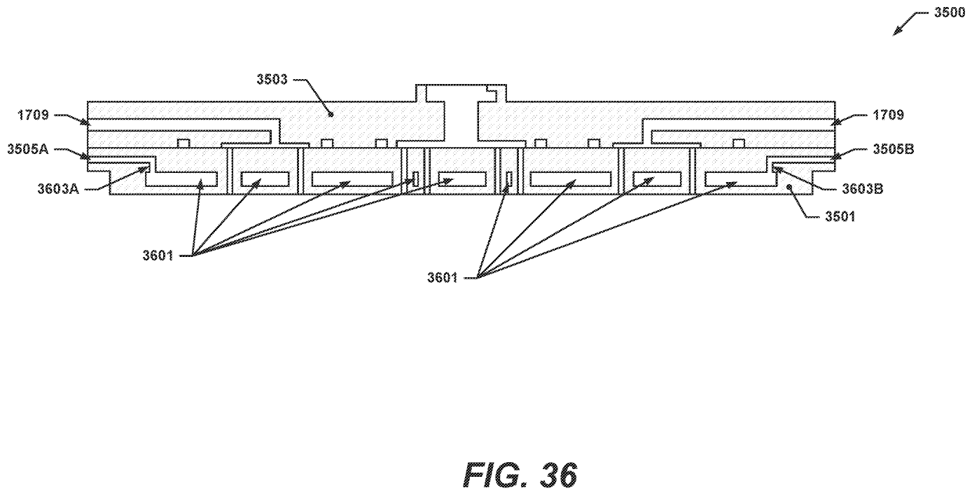

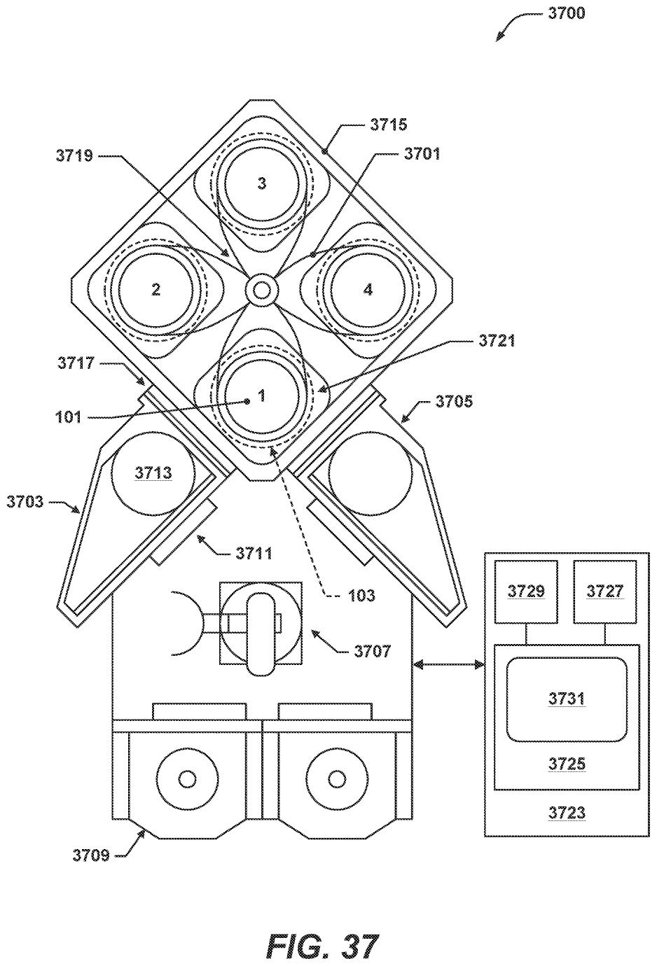

FIG. 35 schematically illustrates a perspective view of a gas distributor in a partially assembled state according to some embodiments. FIG. 36 schematically illustrates a cross-sectional view of the gas distributor of FIG. 35 in the partially assembled state according to some embodiments. It is noted that gas distributor 3500 that will be described in conjunction with FIGS. 35 and 36 may be similar to gas distributor 200 described in association with FIGS. 2-32, and as such, primarily differences will be described below.

Referring to FIGS. 35 and 36, gas distributor 3500 may at least include first and second portions 3501 and 3503 that may be configured similar to first and second portions 201 and 203 of gas distributor 200, however, first portion 3501 may be configured to allow for radial input and output of liquid coolant 131 via radially extending liquid coolant inlet and outlet passages 3505A and 3505B in first portion 3501 versus first and second cooling inlet passages 331A and 333A and first and second cooling outlet passages 331B and 333B as described in association with gas distributor 200. As such, gas distributor 3500 may omit first and second cooling inlet passages 331A and 333A and first and second cooling outlet passages 331B and 333B, as well as those sections of first and second cooling inlet passages 331A and 333A and first and second cooling outlet passages 331B and 333B formed in first and second portions 201 and 203.

According to various embodiments, radially extending liquid coolant inlet and outlet passages 3505A and 3505B may be fluidically connected to liquid cooling passage 3601, which may be configured similar to liquid cooling passage 1201 described in conjunction with FIG. 12. Radially extending liquid coolant inlet and outlet passages 3505A and 3505B may be configured similar to radially extending gas passages 1709 of gas distributor 200, except radially extending liquid coolant inlet and outlet passages 3505A and 3505B may be formed in first portion 3501 and fluidically connected to liquid coolant outlets and inlets 3603B and 3603A, which also be formed in first portion 3501. Liquid coolant outlets and inlets 3603B and 3603A may extend in an axial direction and may be fluidically connected to liquid cooling passage 3601. In this manner, liquid coolant 131 may flow into liquid cooling passage 3601 in first portion 3501 by way of radially extending liquid coolant inlet passages 3311A and liquid coolant outlets 3603B. Similarly, liquid coolant 131 may flow out of liquid cooling passage 3601 in first portion 3501 by way of liquid coolant outlets 3603B and radially extending liquid coolant outlet passages 3505B. A remainder of gas distributor 3500 may be configured substantially similar to gas distributor 200, except first portion 3501 of gas distributor 3500 may be connected to a fourth portion configured similar to third portion 205 described in association with gas distributor 200. The fourth portion of gas distributor 3500, however, may include connection blocks configured to flow liquid coolant 131 into and out of gas distributor 3500 versus connection blocks 209 configured to flow one or more gases into gas distributor 200.

### Multi-station Processing Tool

FIG. 37 schematically illustrates a multi-station processing tool according to some embodiments.

In some implementations, multi-station processing tool 3700 can include an inbound load lock 3703 and an outbound load lock 3705, either or both of which may include a plasma source and/or an ultraviolet (UV) source. Robot 3707, at atmospheric pressure, is configured to move wafers from a cassette loaded through pod 3709 into inbound load lock 3703 via an atmospheric port 3711. Substrate 101 is placed by robot 3707 on pedestal 3713 in inbound load lock 3703, atmospheric port 3711 is closed, and inbound load lock 3703 is pumped down. In instances in which inbound load lock 3703 includes a remote plasma source, substrate 101 may be exposed to a remote plasma treatment in inbound load lock 3703 prior to being introduced into process chamber 3715. In some embodiments, process chamber 121 may form a portion of process chamber 3715. Further, substrate 101 may be heated in inbound load lock 3703 to, for example, remove moisture and/or adsorbed gases. Next, chamber transport port 3717 to process chamber 3715 is opened, and another robot 3719 places wafer 101 into the reactor on a pedestal of a first station shown in the reactor for processing. While the implementation depicted in FIG. 37 includes load locks, it will be appreciated that, in some implementations, direct entry of substrate 101 into a processing station may be provided.

As seen in FIG. 37, process chamber 3715 includes four process stations, numbered 1 to 4. Each station has a gas distributor (such as gas distributor 103 of station 1), and gas line inlets. It will be appreciated that, in some cases, each process station may have different or multiple purposes. For example, in some embodiments, a process station may be switchable between a chemical vapor deposition (CVD) and PECVD process mode. In another example, deposition operations, e.g., PECVD operations, may be performed in one station, while exposure to UV radiation for UV curing may be performed in another station. In some cases, deposition and UV curing may be performed in the same station. Further, although process chamber 3715 shown as including four stations, embodiments are not limited thereto. For example, process chamber 3715 may have any suitable number of stations, such as five or more stations, or three or less stations.

Multi-station processing tool 3700 may include a wafer handling system (e.g., robot 3719 including spider forks 3701) for transferring and/or positioning wafers within process chamber 3715. In some embodiments, the wafer handling system may transfer wafers between various process stations and/or between a process station and a load lock. It is contemplated, however, that any suitable wafer handling system may be employed, such as, for example, wafer carousels, other wafer handling robots, etc. Further, multi-station processing tool 3700 may include (or otherwise be coupled to) a system controller 3723 employed to control process conditions and hardware states of multi-station processing tool 3700. System controller 3723 may include one or more memory devices 3725, one or more mass storage devices 3727, and one or more processors 3729. Each processor 3729 may include a central processing unit (CPU) or computer, analog, and/or digital input/output connections, stepper motor controller boards, etc.

In some embodiments, system controller 3723 controls each of the activities of multi-station processing tool 3700. For instance, system controller 3723 may execute system control software 3731 stored in mass storage device 3727, loaded into memory device 3725, and executed by processor 3729. Alternatively, control logic may be hard coded in system controller 3723. Application specific integrated circuits (ASIC), programmable logic devices (e.g., field-programmable gate arrays (FPGAs)) and/or the like may be used for these purposes. In the following discussion, wherever “software” or “code” is used, functionally comparable hard coded logic may be used in its place. System control software 3731 may include instructions for controlling the relative displacement between substrate supports and gas distributors of a process chamber, timing, mixture of gases, gas flow rates, liquid coolant flow rates through one or more liquid cooling passages (e.g., liquid cooling passages 127) of a gas distributor (e.g., gas distributor 103), flow conductance, temperatures of components forming system 100, chamber and/or station pressure, chamber and/or station temperature, wafer temperature, target power levels, RF power levels, substrate support, chuck and/or susceptor position, and/or other parameters of a particular process performed by multi-station processing tool 3700. For example, various process tool component subroutines or control objects may be written to control operation of the process tool components used to carry out various process tool processes. System control software 3731 may be coded in any suitable computer readable programming language.

In some embodiments, system control software 3731 may include input/output control (IOC) sequencing instructions for controlling the various parameters described above. Other computer software and/or programs stored on mass storage device 3727 and/or memory device 3725 associated with system controller 3723 may be employed in some embodiments. Examples of programs or sections of programs for this purpose include a substrate positioning program, a process gas control program, a pressure control program, a heater control program, a cooler control program, and a plasma control program.

A substrate positioning program may include program code for process tool components that are used to load and orientate wafer 101 (also sometimes referred to as a “substrate”) on pedestal 3721 and to control the spacing between substrate 101 and other parts of multi-station processing tool 3700.

A process gas control program may include code for controlling gas composition (e.g., silicon-containing gases, oxygen-containing gases, nitrogen-containing gases, dilution (or inert) gases, etc.) flow rates, flow conductances, and optionally for flowing gas into one or more process stations prior to deposition to stabilize the pressure in the process station. A pressure control program may include code for controlling the pressure in the process station by regulating, for example, a throttle valve in an exhaust system of the process station, a gas flow into the process station via gas delivery system 147, and/or the like.

A heater control program may include code for controlling current to one or more heating units used to heat a pedestal (e.g., pedestal 3721), a gas distributor (e.g., gas distributor 103) of process chamber 3715, conduits and/or other components of gas delivery system 147, etc. Additionally or alternatively, the heater control program may control delivery of a heat transfer gas (such as helium) to a gas distributor, and, thereby, to substrate 101.

A cooling control program may include code for controlling one or more flow rates of liquid coolant (e.g., liquid coolant 131) through a cooling unit used to extract heat from a pedestal (e.g., pedestal 3721) and/or a gas distributor (e.g., gas distributor 103) of process chamber 3715, and, thereby, transfer such thermal energy to, for instance, a waste heat capturing, storage, recycling, and/or disposing system. The flow of the liquid coolant may also extract heat from substrate 101.

A plasma control program may include code for setting RF power levels applied to the process electrodes in one or more process stations in accordance with various embodiments.

A pressure control program may include code for maintaining pressure in a reaction chamber in accordance with various embodiments.

In some embodiments, a user interface may be provided in association with system controller 3723. The user interface may include a display screen, graphical software displays of the apparatus and/or process conditions, and user input devices, such as pointing devices, keyboards, touch screens, microphones, etc.

In some embodiments, parameters adjusted by system controller 3723 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 3723 from various process tool sensors. The signals for controlling the process may be output on analog and/or digital output connections of multi-station process tool 3700. Non-limiting examples of process tool sensors that may be monitored include mass flow controllers, pressure sensors (such as manometers), thermocouples, etc. Appropriately programmed feedback and control algorithms may be used with data from the sensors to maintain process conditions.

System controller 3723 may provide program instructions for implementing one or more of the above-described processes. The program instructions may control a variety of process parameters, such as direct current (DC) power level, RF bias power level, pressure, temperature, etc. The instructions may control the parameters to operate deposition of film stacks of a stress compensation layer according to various embodiments.

System controller 3723 will typically include one or more memory devices and one or more processors configured to execute the instructions so that the apparatus will perform a method in accordance with some embodiments. In some instances, machine-readable media containing instructions for controlling process operations in accordance with various embodiments may be coupled to system controller 3723.

In some embodiments, system controller 3723 may be part of a system, which may be part of at least one of the above-described examples. Such systems may include semiconductor processing equipment, including a processing tool or tools, a chamber or chambers, a platform or platforms for processing, and/or specific processing components (e.g., a wafer pedestal, a gas flow system, a thermal management system, etc.). The systems discussed above may be integrated with electronics for controlling their operation before, during, and/or after processing of a semiconductor wafer or substrate. The electronics may be referred to as the “controller,” which may control various components or subparts of the system or systems. For instance, system controller 3723, depending on the processing requirements and/or the type of system, may be programmed to control any of the processes disclosed herein, including the delivery of processing gases, temperature settings (e.g., heating and/or cooling), valve operation, flow adjuster operation, light source control for radiative heating, pressure settings, vacuum settings, power settings, RF generator settings, RF matching circuit settings, frequency settings, flow rate settings, fluid delivery settings, positional and operational settings, wafer transfers into and out of a tool or chamber and other transfer tools and/or load locks connected to or interfaced with a specific system. In this manner, system controller 3723 may be configured to control, among other systems, the various actuators and motors of a wafer processing system and flow adjusters of a fluid delivery system.

Broadly speaking, system controller 3723 may be defined as electronics having various integrated circuits, logic, memory, and/or software that receive instructions, issue instructions, control operation, enable cleaning operations, enable endpoint measurements, and/or the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to system controller 3723 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, dies of a wafer, etc.

System controller 3723, in some implementations, may be a part of or coupled to a computer that is integrated with, coupled to the system, otherwise networked to the system, or a combination thereof. For example, system controller 3723 may be in the “cloud” or all or a part of a fab host computer system, which can allow for remote access of wafer processing.

The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It is to be understood that the parameters may be specific to the type of process to be performed and the type of tool that the controller is configured to interface with or control. Thus, as described above, system controller 3723 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and/or any other semiconductor processing system that may be associated or used in the fabrication and/or manufacturing of semiconductor wafers.

As noted above, depending on the process step or steps to be performed by the tool, system controller 3723 might communicate with one or more of other tool circuits or modules, other tool components, cluster tools, other tool interfaces, adjacent tools, neighboring tools, tools located throughout a factory, a main computer, another controller, and/or tools used in material transport that bring containers of wafers to and from tool locations and/or load ports in a semiconductor manufacturing factory.

### Additional And/or Alternative Embodiments

Certain embodiments are directed to apparatus including: a first surface; a second surface opposing the first surface in a first direction; a plurality of first gas distribution ports extending in the first direction and being fluidically connected to at least one first gas inlet, the first gas distribution ports having respective distal ends forming first gas distribution openings in the first surface; a first gas distribution plenum interposed between the first and second surfaces, the first gas distribution plenum being fluidically connected between the at least one first gas inlet and respective proximal ends of the first gas distribution ports; and one or more liquid cooling passages interposed between the first and second surfaces. In these embodiments, a reference plane extending in a second direction transverse to the first direction extends through central portions of the one or more liquid cooling passages, the reference plane being interposed between the first gas distribution plenum and the first surface in the first direction; and between the first and second surfaces, the one or more liquid cooling passages are fluidically isolated from the first gas distribution plenum. In some of these embodiments, the fourth surface of the cooling layer comprises: a coolant inlet opening forming a proximal end of a first portion of the coolant inlet passage, a distal end of the first portion of the coolant inlet passage being fluidically connected to at least one of the one or more liquid cooling passages; and a coolant outlet opening forming a distal end of a first portion of the coolant outlet passage, a proximal end of the first portion of the coolant outlet passage being fluidically connected to at least one of the one or more liquid cooling passages; the first portion of the coolant inlet passage extends in a fourth direction; and the first portion of the coolant outlet passage extends in the fourth direction. In some cases, the cooling inlet passage is one of a plurality of cooling inlet passages fluidically connected to the one or more liquid cooling passages; the cooling outlet passage is one of a plurality of cooling outlet passages fluidically connected to the one or more liquid cooling passages; each of the cooling inlet passages comprises a section extending in the third direction from a corresponding coolant inlet opening in the fourth surface towards the first surface; and each of the cooling outlet passages comprises a section extending in the third direction from a corresponding coolant outlet opening in the fourth surface towards the first surface.

Certain embodiments are directed to apparatus including: a first surface; a second surface opposing the first surface in a first direction; a plurality of first gas distribution ports extending in the first direction and being fluidically connected to at least one first gas inlet, the first gas distribution ports having respective distal ends forming first gas distribution openings in the first surface; a first gas distribution plenum interposed between the first and second surfaces, the first gas distribution plenum being fluidically connected between the at least one first gas inlet and respective proximal ends of the first gas distribution ports; and one or more liquid cooling passages interposed between the first and second surfaces. In these embodiments, a reference plane extending in a second direction transverse to the first direction extends through central portions of the one or more liquid cooling passages, the reference plane being interposed between the first gas distribution plenum and the first surface in the first direction; and between the first and second surfaces, the one or more liquid cooling passages are fluidically isolated from the first gas distribution plenum. In some of these embodiments, the one or more liquid cooling passages correspond to a single liquid cooling passage. In one embodiment, the single liquid cooling passage has a cylindrical configuration. In some others of the embodiments, in a view in the first direction, the one or more liquid cooling passages comprise a first liquid cooling passage and a second liquid cooling passage encircling the first liquid cooling passage. In one aspect, in the view in the first direction, the first and second liquid cooling passages have annular configurations. In one example, the first and second liquid cooling passages encircle a central axis extending through the first and second surfaces in the first direction; and the one or more liquid cooling passages further comprise one or more third liquid cooling passages extending radially from the central axis. In one example, also the apparatus the first, second, and one or more third liquid cooling passages are fluidically connected to one another between the first and second surfaces.

Certain embodiments are directed to apparatus including: a first surface; a second surface opposing the first surface in a first direction; a plurality of first gas distribution ports extending in the first direction and being fluidically connected to at least one first gas inlet, the first gas distribution ports having respective distal ends forming first gas distribution openings in the first surface; a first gas distribution plenum interposed between the first and second surfaces, the first gas distribution plenum being fluidically connected between the at least one first gas inlet and respective proximal ends of the first gas distribution ports; and one or more liquid cooling passages interposed between the first and second surfaces. In these embodiments, a reference plane extending in a second direction transverse to the first direction extends through central portions of the one or more liquid cooling passages, the reference plane being interposed between the first gas distribution plenum and the first surface in the first direction; and between the first and second surfaces, the one or more liquid cooling passages are fluidically isolated from the first gas distribution plenum. In some embodiments, in a view in the first direction, the one or more liquid cooling passages form a fractal pattern. In other embodiments, the cooling layer further comprises a fifth surface extending between the third and fourth surfaces, the fifth surface comprising: a coolant inlet opening forming a proximal end of the coolant inlet passage; and a coolant outlet opening forming a distal end of the coolant outlet passage; the coolant inlet passage comprises a first portion extending in a second direction transverse to the first direction; and the coolant outlet passage comprises a second portion extending in a third direction transverse of the first direction. Also, the coolant inlet passage further comprises a third portion fluidically connected between the first portion and the at least one of the one or more liquid cooling passages; the coolant outlet passage further comprises a fourth portion fluidically connected between the second portion and the at least one of the one or more liquid cooling passages; and the third and fourth portions extend in a fourth direction transverse to each of the second and third directions. In addition, the apparatus further comprises a gas distribution layer comprising a sixth surface and a seventh surface opposing the sixth surface in the first direction, wherein the gas distribution layer further comprises the first gas distribution plenum interposed between the sixth and seventh surfaces. In some cases, the gas distribution layer further comprises: an eighth surface extending between the sixth and seventh surfaces; and a first gas inlet passage fluidically connected to the first gas distribution plenum; the eight surface comprises the first gas inlet forming a proximal end of the first gas inlet passage; and the first gas inlet passage comprises a first portion extending in a fifth direction transverse to the first direction. In one case, the first gas inlet passage further comprises a second portion fluidically connected between the first portion of the first gas inlet passage and the first gas distribution plenum; and the second portion of the first gas inlet passage extends in a sixth direction transverse to the fifth direction. According to one aspect, the first and sixth directions are equivalent. According to another aspect, the first gas inlet passage is one of a plurality of first gas inlet passages fluidically connected to the first gas distribution plenum; and each of the first gas inlet passages comprises a section extending radially inwards from a corresponding first gas inlet in the eighth surface towards a central portion of the gas distribution layer.

Certain embodiments are directed to apparatus including: a first surface; a second surface opposing the first surface in a first direction; a plurality of first gas distribution ports extending in the first direction and being fluidically connected to at least one first gas inlet, the first gas distribution ports having respective distal ends forming first gas distribution openings in the first surface; a first gas distribution plenum interposed between the first and second surfaces, the first gas distribution plenum being fluidically connected between the at least one first gas inlet and respective proximal ends of the first gas distribution ports; and one or more liquid cooling passages interposed between the first and second surfaces. In these embodiments, a reference plane extending in a second direction transverse to the first direction extends through central portions of the one or more liquid cooling passages, the reference plane being interposed between the first gas distribution plenum and the first surface in the first direction; and between the first and second surfaces, the one or more liquid cooling passages are fluidically isolated from the first gas distribution plenum. In some embodiments, in a view in the first direction, the one or more liquid cooling passages form a fractal pattern. In other embodiments, the cooling layer further comprises a fifth surface extending between the third and fourth surfaces, the fifth surface comprising: a coolant inlet opening forming a proximal end of the coolant inlet passage; and a coolant outlet opening forming a distal end of the coolant outlet passage; the coolant inlet passage comprises a first portion extending in a second direction transverse to the first direction; and the coolant outlet passage comprises a second portion extending in a third direction transverse of the first direction. Also, the coolant inlet passage further comprises a third portion fluidically connected between the first portion and the at least one of the one or more liquid cooling passages; the coolant outlet passage further comprises a fourth portion fluidically connected between the second portion and the at least one of the one or more liquid cooling passages; and the third and fourth portions extend in a fourth direction transverse to each of the second and third directions. In addition, the apparatus further comprises a gas distribution layer comprising a sixth surface and a seventh surface opposing the sixth surface in the first direction, wherein the gas distribution layer further comprises the first gas distribution plenum interposed between the sixth and seventh surfaces. In these embodiments, the gas distribution layer further comprises: a second portion of the coolant inlet passage extending from the sixth surface through the seventh surface, the second portion of the coolant inlet passage being fluidically connected to the first portion of the coolant inlet passage; and a second portion of the coolant outlet passage extending from the sixth surface through the seventh surface, the second portion of the coolant outlet passage being fluidically connected to the first portion of the coolant outlet passage.

Certain embodiments are directed to apparatus including: a first surface; a second surface opposing the first surface in a first direction; a plurality of first gas distribution ports extending in the first direction and being fluidically connected to at least one first gas inlet, the first gas distribution ports having respective distal ends forming first gas distribution openings in the first surface; a first gas distribution plenum interposed between the first and second surfaces, the first gas distribution plenum being fluidically connected between the at least one first gas inlet and respective proximal ends of the first gas distribution ports; and one or more liquid cooling passages interposed between the first and second surfaces. In these embodiments, a reference plane extending in a second direction transverse to the first direction extends through central portions of the one or more liquid cooling passages, the reference plane being interposed between the first gas distribution plenum and the first surface in the first direction; and between the first and second surfaces, the one or more liquid cooling passages are fluidically isolated from the first gas distribution plenum. In some embodiments, in a view in the first direction, the one or more liquid cooling passages form a fractal pattern. In other embodiments, the cooling layer further comprises a fifth surface extending between the third and fourth surfaces, the fifth surface comprising: a coolant inlet opening forming a proximal end of the coolant inlet passage; and a coolant outlet opening forming a distal end of the coolant outlet passage; the coolant inlet passage comprises a first portion extending in a second direction transverse to the first direction; and the coolant outlet passage comprises a second portion extending in a third direction transverse of the first direction. Also, the coolant inlet passage further comprises a third portion fluidically connected between the first portion and the at least one of the one or more liquid cooling passages; the coolant outlet passage further comprises a fourth portion fluidically connected between the second portion and the at least one of the one or more liquid cooling passages; and the third and fourth portions extend in a fourth direction transverse to each of the second and third directions. In addition, the apparatus further comprises a gas distribution layer comprising a sixth surface and a seventh surface opposing the sixth surface in the first direction, wherein the gas distribution layer further comprises the first gas distribution plenum interposed between the sixth and seventh surfaces. The apparatus further comprises: a plurality of second gas distribution ports extending in the first direction and being fluidically connected to a second gas inlet, the second gas distribution ports having respective distal ends forming second gas distribution openings in the first surface; and a second gas distribution plenum interposed between the first and second surfaces, the second gas distribution plenum being fluidically connected between the second gas inlet and respective proximal ends of the second gas distribution ports. Also, the first gas distribution ports encircle the second gas distribution ports; and the first gas distribution plenum encircles the second gas distribution plenum.

Certain embodiments are directed to apparatus including: a first surface; a second surface opposing the first surface in a first direction; a plurality of first gas distribution ports extending in the first direction and being fluidically connected to at least one first gas inlet, the first gas distribution ports having respective distal ends forming first gas distribution openings in the first surface; a first gas distribution plenum interposed between the first and second surfaces, the first gas distribution plenum being fluidically connected between the at least one first gas inlet and respective proximal ends of the first gas distribution ports; and one or more liquid cooling passages interposed between the first and second surfaces. In these embodiments, a reference plane extending in a second direction transverse to the first direction extends through central portions of the one or more liquid cooling passages, the reference plane being interposed between the first gas distribution plenum and the first surface in the first direction; and between the first and second surfaces, the one or more liquid cooling passages are fluidically isolated from the first gas distribution plenum. Also, the apparatus further comprises a process chamber having an internal cavity, wherein the first surface faces the internal cavity in the first direction. In one embodiment, the process chamber defines a transformer-coupled plasma etch chamber. In another embodiment, the apparatus further comprises an inductive coupling structure supported on the second surface.

Certain embodiments are directed to apparatus including: a first surface; a second surface opposing the first surface in a first direction; a plurality of first gas distribution ports extending in the first direction and being fluidically connected to at least one first gas inlet, the first gas distribution ports having respective distal ends forming first gas distribution openings in the first surface; a first gas distribution plenum interposed between the first and second surfaces, the first gas distribution plenum being fluidically connected between the at least one first gas inlet and respective proximal ends of the first gas distribution ports; and one or more liquid cooling passages interposed between the first and second surfaces. In these embodiments, a reference plane extending in a second direction transverse to the first direction extends through central portions of the one or more liquid cooling passages, the reference plane being interposed between the first gas distribution plenum and the first surface in the first direction; and between the first and second surfaces, the one or more liquid cooling passages are fluidically isolated from the first gas distribution plenum. In one embodiment, the liquid coolant is non-conductive. In another embodiment, the liquid coolant is non-polar. In another embodiment, the liquid coolant comprises at least one of a polyfluorinated compound, a perfluorinated compound, a segregated hydrofluoroether compound, a metal oxide, and a carbon nanotube.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items-it is to be understood that a set or a subset can encompass only one member or multiple members (unless the context indicates otherwise). The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Accordingly, the term “substantially” as used herein, unless otherwise specified, means within 5% of a referenced value. For example, substantially perpendicular means within ±5% of parallel.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element, it may be directly on, directly connected to, or directly coupled to the other element or at least one intervening element may be present. When, however, an element is referred to as being “directly on,” “directly connected to,” or “directly coupled to” another element, there are no intervening elements present. Other terms and/or phrases if used herein to describe a relationship between elements should be interpreted in a like fashion, such as “between” versus “directly between,” “adjacent” versus “directly adjacent,” “on” versus “directly on,” etc. Further, the term “connected” may refer to physical, electrical, and/or fluid connection. To this end, for the purposes of this disclosure, the phrase “fluidically connected” is used with respect to volumes, plenums, holes, etc., that may be connected to one another, either directly or via one or more intervening components or volumes, to form a fluidic connection, similar to how the phrase “electrically connected” is used with respect to components that are connected to form an electric connection. The phrase “fluidically interposed,” if used, may be used to refer to a component, volume, plenum, hole, etc., that is fluidically connected with at least two other components, volumes, plenums, holes, etc., such that fluid flowing from one of those other components, volumes, plenums, holes etc., to the other or another of those components, volumes, plenums, holes, etc., would first flow through the “fluidically interposed” component before reaching that other or another of those components, volumes, plenums, holes, etc. For example, if a pump is fluidically interposed between a reservoir and an outlet, fluid flowing from the reservoir to the outlet would first flow through the pump before reaching the outlet. The phrase “fluidically adjacent,” if used, refers to placement of a fluidic element relative to another fluidic element such that no potential structures fluidically are interposed between the two elements that might potentially interrupt fluid flow between the two fluidic elements. For example, in a flow path having a first valve, a second valve, and a third valve arranged sequentially therealong, the first valve would be fluidically adjacent to the second valve, the second valve fluidically adjacent to both the first and third valves, and the third valve fluidically adjacent to the second valve.

For the purposes of this disclosure, “at least one of X, Y,. and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. As used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.” Further, the use, if any, of ordinal indicators, such as (a), (b), (c), . . . , or (1), (2), (3), . . . , or the like, in this disclosure and accompanying claims, is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated), unless indicated otherwise. For example, if step (ii) involves the handling of an element that is created in step (i), then step (ii) may be viewed as happening at some point after step (i). In a similar manner, if step (i) involves the handling of an element that is created in step (ii), the reverse is to be understood.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “between,” as used herein and when used with a range of values, is to be understood, unless otherwise indicated, as being inclusive of the start and end values of that range. For example, between 1 and 5 is to be understood as inclusive of the numbers 1, 2, 3, 4, and 5, not just the numbers 2, 3, and 4.

As used herein, the phrase “operatively connected” is to be understood as referring to a state in which two components and/or systems are connected, either directly or indirectly, such that, for example, at least one component or system can control the other. For instance, a controller may be described as being operatively connected with (or to) a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely will not supply such power directly to the resistive heating unit due to the current(s) involved, but it is to be understood that the controller is nonetheless operatively connected with the resistive heating unit.

As used herein, the singular forms, “a,” “an,” and “the” are intended to include the plural forms as well, unless the context clearly indicates otherwise. It is also to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced.

For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items—it is to be understood that a set or a subset can encompass only one member or multiple members (unless the context indicates otherwise). In addition, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional views, isometric views, perspective views, plan views, and/or exploded illustrations that are schematic depictions of idealized embodiments and/or intermediate structures. As such, variations from the shapes of the illustrations as a result of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and, as such, are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and are not to be interpreted in an idealized or overly formal sense, unless expressly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the inventive concepts. Further, the blocks, units, and/or modules of some embodiments may be physically combined into more complex blocks, units, and/or modules without departing from the teachings of the disclosure.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered as illustrative and not as restrictive, and embodiments are not to be limited to the details given herein.

1. An apparatus comprising:
a first surface;
a second surface opposing the first surface in a first direction;
a plurality of first gas distribution ports extending in the first direction and being fluidically connected to at least one first gas inlet, the first gas distribution ports having respective distal ends forming first gas distribution openings in the first surface;
a first gas distribution plenum interposed between the first and second surfaces, the first gas distribution plenum being fluidically connected between the at least one first gas inlet and respective proximal ends of the first gas distribution ports; and
one or more liquid cooling passages interposed between the first and second surfaces, wherein:
a reference plane extending in a second direction transverse to the first direction extends through central portions of the one or more liquid cooling passages, the reference plane being interposed between the first gas distribution plenum and the first surface in the first direction,
the one or more liquid cooling passages are fluidically isolated from the first gas distribution plenum between the first and second surfaces, and
respective widths of the one or more liquid cooling passages in at least one direction perpendicular to the first direction are greater than respective heights of the one or more liquid cooling passages in the first direction.

2. The apparatus of claim 1, further comprising:
a cooling layer comprising a third surface and a fourth surface opposing the third surface in the first direction,
wherein the cooling layer further comprises:
the one or more liquid cooling passages interposed between the third and fourth surfaces; and
respective portions of the first gas distribution ports extending from the third surface through the fourth surface.

3. The apparatus of claim 2, wherein the third surface defines the first surface.

4. The apparatus of claim 2, wherein the cooling layer further comprises:
a coolant inlet passage fluidically connected to at least one of the one or more liquid cooling passages; and
a coolant outlet passage fluidically connected to at least one of the one or more liquid cooling passages, wherein:
the cooling layer further comprises a fifth surface extending between the third and fourth surfaces, the fifth surface comprising:
a coolant inlet opening forming a proximal end of the coolant inlet passage; and
a coolant outlet opening forming a distal end of the coolant outlet passage;
the coolant inlet passage comprises a first portion extending in a second direction transverse to the first direction; and
the coolant outlet passage comprises a second portion extending in a third direction transverse of the first direction.

5. (canceled)

6. The apparatus of claim 4, wherein:
the coolant inlet passage further comprises a third portion fluidically connected between the first portion and the at least one of the one or more liquid cooling passages;
the coolant outlet passage further comprises a fourth portion fluidically connected between the second portion and the at least one of the one or more liquid cooling passages; and
the third and fourth portions extend in a fourth direction transverse to each of the second and third directions.

7. The apparatus of either claim 4, wherein:
the cooling inlet passage is one of a plurality of cooling inlet passages fluidically connected to the one or more liquid cooling passages;
the cooling outlet passage is one of a plurality of cooling outlet passages fluidically connected to the one or more liquid cooling passages;
each of the cooling inlet passages comprises a section extending radially inwards from a corresponding coolant inlet opening in the fifth surface towards a central portion of the cooling layer; and
each of the cooling outlet passages comprises a section extending radially inwards from a corresponding coolant outlet opening in the fifth surface towards the central portion of the cooling layer.

8. The apparatus of claim 4, wherein:
the fourth surface of the cooling layer comprises:
a coolant inlet opening forming a proximal end of a first portion of the coolant inlet passage, a distal end of the first portion of the coolant inlet passage being fluidically connected to at least one of the one or more liquid cooling passages; and
a coolant outlet opening forming a distal end of a first portion of the coolant outlet passage, a proximal end of the first portion of the coolant outlet passage being fluidically connected to at least one of the one or more liquid cooling passages;
the first portion of the coolant inlet passage extends in a fourth direction; and
the first portion of the coolant outlet passage extends in the fourth direction.

9. The apparatus of either claim 6, wherein the first and fourth directions are equivalent.

10. The apparatus of claim 7, wherein:
the one or more liquid cooling passages are a plurality of liquid cooling passages;
each of the plurality of cooling inlet passages is fluidically connected to a corresponding cooling passage among the liquid cooling passages; and
each of the plurality of cooling outlet passages is fluidically connected to a corresponding cooling passage among the liquid cooling passages.

11. The apparatus of claim 2, wherein the cooling layer comprises a plurality of cooling layers connected to one another and the one or more liquid cooling passages define recesses formed in at least one of the cooling layers.

12. (canceled)

13. (canceled)

14. The apparatus of claim 1, wherein the one or more liquid cooling passages comprise one or more structures configured to induce turbulent flow along the one or more liquid cooling passages.

15. The apparatus of claim 1, wherein, in a view in the first direction, the one or more liquid cooling passages have one or more serpentine configurations.

16. The apparatus of claim 15, wherein, in the view in the first direction, the one or more serpentine configurations follow a path about a central axis extending through the first and second surfaces in the first direction.

17. The apparatus of claim 1, wherein at least one of the first gas distribution ports is positioned outside the one or more liquid cooling passages.

18. The apparatus of claim 17, wherein:
at least one of the first gas distribution ports is positioned inside the one or more liquid cooling passages.

19. The apparatus of claim 5, further comprising:
a gas distribution layer comprising a sixth surface and a seventh surface opposing the sixth surface in the first direction,
wherein the gas distribution layer further comprises the first gas distribution plenum interposed between the sixth and seventh surfaces.

20. The apparatus of claim 19, wherein the sixth surface defines the second surface.

21. The apparatus of claim 19, wherein the apparatus further comprises:
a plurality of second gas distribution ports extending in the first direction and being fluidically connected to a second gas inlet, the second gas distribution ports having respective distal ends forming second gas distribution openings in the first surface; and
a second gas distribution plenum interposed between the first and second surfaces, the second gas distribution plenum being fluidically connected between the second gas inlet and respective proximal ends of the second gas distribution ports.

22. The apparatus of claim 15, further comprising:
a process chamber having an internal cavity, wherein the first surface faces the internal cavity in the first direction.

23. (canceled)

24. The apparatus of claim 22, further comprising:
a pedestal configured to support a semiconductor wafer within the internal cavity, wherein the pedestal faces the first surface in the first direction.

25. (canceled)
